(19) United States
(12) Patent Application Publication
(10) Pub. No.: US 2024/0224613 A1
(43) Pub. Date: Jul. 4, 2024

(54) DISPLAY DEVICE

(71) Applicant: LG Display Co., Ltd., Seoul (KR)

(72) Inventor: DongYoon KIM, Seongnam-si (KR)

(21) Appl. No.: 18/529,525

(22) Filed: Dec. 5, 2023

(30) Foreign Application Priority Data
Dec. 30, 2022 (KR) 10-2022-0190362

(51) Int. Cl. H10K 59/122; H10K 59/124; H10K 59/80

(52) U.S. Cl. CPC H10K 59/122; H10K 59/124; H10K 59/873

(57) ABSTRACT

A display device according to the present disclosure includes a first substrate which is formed of one of transparent conducting oxide and an oxide semiconductor, an inorganic layer which is disposed on the first substrate and has an end located at the inside of the first substrate, a planarization layer disposed on the inorganic layer and the first substrate, and a bank disposed on the planarization layer. The planarization layer includes a first planarization layer disposed in an area which overlaps the inorganic layer and a second planarization layer disposed to cover a top surface of the first substrate exposed by the inorganic layer, the bank includes a first bank disposed on the first planarization layer and a second bank disposed on the second planarization layer, and thicknesses of the second planarization layer and the second bank are smaller than thicknesses of the first planarization layer and the first bank.

### CROSS-REFERENCE TO RELATED APPLICATIONS

This application claims the priority of Korean Patent Application No. 10-2022-0190362 filed on Dec. 30, 2022, in the Korean Intellectual Property Office, the disclosure of which is incorporated herein by reference.

### BACKGROUND

### Technical Field

The present disclosure relates to a display device and more particularly, to a display device that reduces moisture permeation from an outer peripheral side surface.

### Description of the Related Art

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Further, recently, a flexible display device which is manufactured by forming a display element and a wiring line on a flexible substrate such as plastic which is a flexible material so as to be capable of displaying images even in a folded or rolled state is getting attention as a next generation display device.

### BRIEF SUMMARY

The present disclosure provides a display device which uses one of a transparent conducting oxide layer and an oxide semiconductor layer as a substrate, instead of a plastic substrate.

The present disclosure provides a display device which blocks a moisture permeation path in an outer peripheral portion.

The present disclosure provides a display device which reduces a defect of a light emitting diode caused by the moisture permeation.

The present disclosure is not limited to the above-mentioned technical features and benefits, and other technical features and benefits, which are not mentioned above, can be clearly understood by those skilled in the art from the following descriptions.

According to an aspect of the present disclosure, a display device includes a first substrate which includes an active area including a plurality of sub pixels and a non-active area enclosing the active area and is formed of one of transparent conducting oxide and an oxide semiconductor; an inorganic layer which is disposed on the first substrate and has an end located at the inside of the first substrate; a planarization layer disposed on the inorganic layer and the first substrate, and a bank disposed on the planarization layer. The planarization layer includes a first planarization layer disposed in an area which overlaps the inorganic layer and a second planarization layer disposed to cover a top surface of the first substrate exposed by the inorganic layer. The bank includes a first bank disposed on the first planarization layer and a second bank disposed on the second planarization layer and thicknesses of the second planarization layer and the second bank are smaller than thicknesses of the first planarization layer and the first bank. By doing this, the moisture permeation through organic layers in the outer peripheral portion may be reduced.

According to another aspect of the present disclosure, a display device includes a first substrate which includes an active area and a non-active area enclosing the active area and is formed of one of transparent conducting oxide and an oxide semiconductor; an inorganic layer which is disposed on the first substrate and has an end located at the inside of the first substrate in the non-active area; a first planarization layer disposed on the inorganic layer; a second planarization layer which is disposed in the non-active area of the first substrate whose top surface is exposed by the inorganic layer; a first bank disposed on the first planarization layer; a plurality of first moisture permeation suppression patterns disposed on the second planarization layer; a second bank disposed on the first moisture permeation suppression pattern; and a plurality of second moisture permeation suppression patterns disposed on the second bank. The non-active area includes a first non-active area in which a gate driver is disposed, a second non-active area between the plurality of flexible films in an area connected to a plurality of flexible films, and a third non-active area which is an opposite area to the area connected to the plurality of flexible films. The plurality of first moisture permeation suppression patterns and the plurality of second moisture permeation suppression patterns disposed in the first non-active area are different from the plurality of first moisture permeation suppression patterns and the plurality of second moisture permeation suppression patterns disposed in the second non-active area and the third non-active area. Accordingly, the crack propagation is reduced while minimizing the moisture permeation of the outer peripheral portion.

Other detailed matters of the exemplary embodiments are included in the detailed description and the drawings.

According to the present disclosure, a transparent conductive oxide layer and an oxide semiconductor layer are used as a substrate of the display device to easily control a moisture permeability and improve a flexibility.

According to the present disclosure, moisture permeation which may be generated in an outer peripheral portion may be reduced by adjusting thicknesses of a planarization layer and a bank disposed in the non-active area which does not overlap the inorganic layer.

According to the present disclosure, a plurality of moisture permeation suppression patterns formed of an inorganic material is disposed in a non-active area which does not overlap an inorganic layer to increase a moisture permeation path of the outer peripheral portion, thereby delaying moisture permeation.

According to the present disclosure, a plurality of moisture permeation suppression patterns and a plurality of metal patterns formed of an inorganic material are disposed in a non-active area which does not overlap an inorganic layer to increase a moisture permeation path of the outer peripheral portion, thereby minimizing the propagation of the crack.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure;

FIG. 2 is a schematic cross-sectional view of a display device according to an exemplary embodiment of the present disclosure;

FIG. 3 is a circuit diagram of a sub pixel of a display device according to an exemplary embodiment of the present disclosure;

FIG. 4 is an enlarged plan view of one pixel of a display device according to an exemplary embodiment of the present disclosure;

FIG. 5 is a cross-sectional view taken along the line V-V′ of FIG. 4;

FIG. 6A is a cross-sectional view of a first exemplary embodiment taken along the line VIa-VIa′ of FIG. 1;

FIG. 6B is a cross-sectional view of a first exemplary embodiment taken along VIb-VIb′ of FIG. 1;

FIG. 6C is a cross-sectional view of a first exemplary embodiment taken along VIc-VIc′ of FIG. 1;

FIG. 7A is a cross-sectional view of a second exemplary embodiment taken along the line VIa-VIa′ of FIG. 1;

FIG. 7B is a cross-sectional view of a second exemplary embodiment taken along VIb-VIb′ of FIG. 1;

FIG. 7C is a cross-sectional view of a second exemplary embodiment taken along VIc-VIc′ of FIG. 1;

FIG. 8A is a cross-sectional view of a third exemplary embodiment taken along the line VIa-VIa′ of FIG. 1;

FIG. 8B is a cross-sectional view of a third exemplary embodiment taken along VIb-VIb′ of FIG. 1;

FIG. 8C is a cross-sectional view of a third exemplary embodiment taken along VIc-VIc′ of FIG. 1;

FIG. 9A is a cross-sectional view of a fourth exemplary embodiment taken along the line VIa-VIa′ of FIG. 1;

FIG. 9B is a cross-sectional view of a fourth exemplary embodiment taken along VIb-VIb′ of FIG. 1;

FIG. 9C is a cross-sectional view of a fourth exemplary embodiment taken along VIc-VIc′ of FIG. 1;

FIGS. 10A and 10B are schematic enlarged plan views of an area A of FIG. 1 according to a fourth exemplary embodiment;

FIG. 10C is a schematic enlarged plan view of an area B of FIG. 1 according to a fourth exemplary embodiment;

FIG. 10D is a schematic enlarged plan view of an area C of FIG. 1 according to a fourth exemplary embodiment;

FIG. 11A is a cross-sectional view of a fifth exemplary embodiment taken along the line VIa-VIa′ of FIG. 1;

FIG. 11B is a cross-sectional view of a fifth exemplary embodiment taken along VIb-VIb′ of FIG. 1;

FIG. 11C is a cross-sectional view of a fifth exemplary embodiment taken along VIc-VIc′ of FIG. 1;

FIG. 12A is a schematic enlarged plan view of an area A of FIG. 1 according to a fifth exemplary embodiment;

FIG. 12B is a schematic enlarged plan view of an area B of FIG. 1 according to a fifth exemplary embodiment;

FIG. 12C is a schematic enlarged plan view of an area C of FIG. 1 according to a fifth exemplary embodiment;

FIG. 13A is a cross-sectional view of a sixth exemplary embodiment taken along the line VIa-VIa′ of FIG. 1;

FIG. 13B is a cross-sectional view of a sixth exemplary embodiment taken along VIb-VIb′ of FIG. 1;

FIG. 13C is a cross-sectional view of a sixth exemplary embodiment taken along VIc-VIc′ of FIG. 1;

FIG. 14A is a schematic enlarged plan view of an area A of FIG. 1 according to a sixth exemplary embodiment;

FIG. 14B is a schematic enlarged plan view of an area B of FIG. 1 according to a sixth exemplary embodiment;

FIG. 14C is a schematic enlarged plan view of an area C of FIG. 1 according to a sixth exemplary embodiment;

FIGS. 15A and 15B are schematic enlarged plan views illustrating an example of another shape of a permeation suppression pattern according to a sixth exemplary embodiment;

FIG. 16A is a cross-sectional view of a seventh exemplary embodiment taken along the line VIa-VIa′ of FIG. 1;

FIG. 16B is a cross-sectional view of a seventh exemplary embodiment taken along VIb-VIb′ of FIG. 1;

FIG. 16C is a cross-sectional view of a seventh exemplary embodiment taken along VIc-VIc′ of FIG. 1;

FIG. 17A is a cross-sectional view of an eighth exemplary embodiment taken along the line VIa-VIa′ of FIG. 1;

FIG. 17B is a cross-sectional view of an eighth exemplary embodiment taken along VIb-VIb′ of FIG. 1;

FIG. 17C is a cross-sectional view of an eighth exemplary embodiment taken along VIc-VIc′ of FIG. 1;

FIG. 18A is a schematic enlarged plan view of an area A of FIG. 1 according to an eighth exemplary embodiment;

FIG. 18B is a schematic enlarged plan view of an area B of FIG. 1 according to an eighth exemplary embodiment; and

FIG. 18C is a schematic enlarged plan view of an area C of FIG. 1 according to an eighth exemplary embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The term “exemplary” as used herein includes and means a suitable example and does not mean and is not limited to a required or preferred example.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

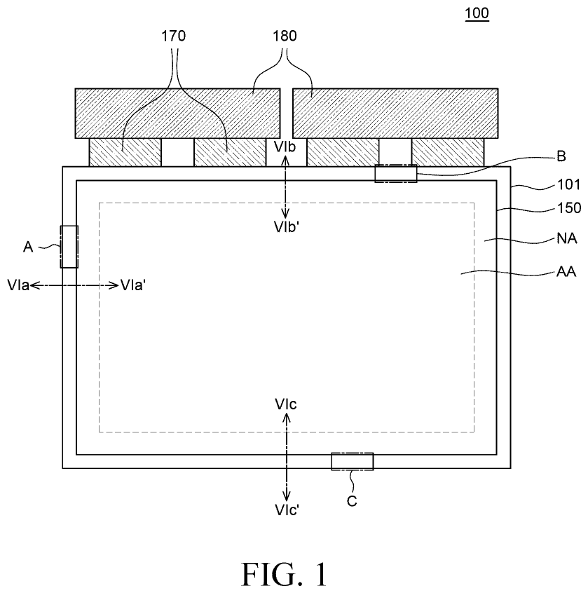

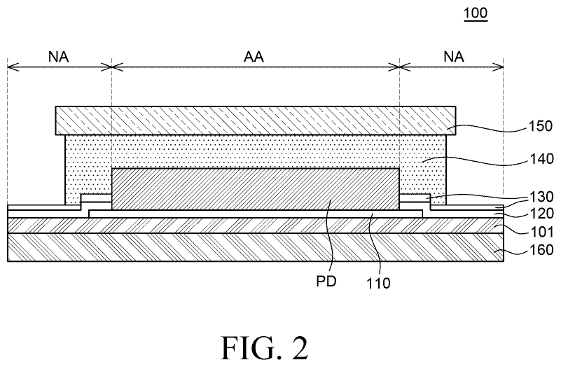

FIG. 1 is a plan view of a display device according to an exemplary embodiment of the present disclosure. FIG. 2 is a schematic cross-sectional view of a display device according to an exemplary embodiment of the present disclosure. For the convenience of description, in FIG. 1, among various components of the display device 100, only a first substrate 101, a second substrate 150, a plurality of flexible films 170, and a plurality of printed circuit boards 180 are illustrated.

Referring to FIGS. 1 and 2, the first substrate 101 is a support member which supports other components of the display device 100. The first substrate 101 may be formed of any one of a transparent conducting oxide and an oxide semiconductor. For example, the first substrate 101 may be formed of a transparent conducting oxide (TCO), such as indium tin oxide (ITO), indium zinc oxide (IZO), or indium tin zinc oxide (ITZO).

Further, the first substrate 101 may be formed of an oxide semiconductor material formed of indium (In) and gallium (Ga), for example, a transparent oxide semiconductor such as indium gallium zinc oxide (IGZO), indium gallium oxide (IGO), and indium tin zinc oxide (ITZO). However, a type of a material of the transparent conducting oxide and the oxide semiconductor is illustrative so that the first substrate 101 may be formed by another transparent conducting oxide and oxide semiconductor material which have not been described in the specification, but is not limited thereto.

In the meantime, the first substrate 101 may be formed by depositing the transparent conducting oxide or the oxide semiconductor with a very thin thickness. Therefore, as the first substrate 101 is formed to have a very thin thickness, the first substrate has a flexibility. A display device 100 including the first substrate 101 having a flexibility may be implemented as a flexible display device 100 which displays an image even in a folded or rolled state. For example, when the display device 100 is a foldable display device, the first substrate 101 is folded or unfolded with respect to a folding axis. As another example, when the display device 100 is a rollable display device, the display device may be rolled around the roller to be stored. Accordingly, the display device 100 according to the exemplary embodiment of the present disclosure uses the first substrate 101 having a flexibility to be implemented as a flexible display device 100, like a foldable display device or a rollable display device.

Further, the display device 100 according to the exemplary embodiment of the present disclosure uses the first substrate 101 formed of a transparent conducting oxide or an oxide semiconductor to perform a laser lift off (LLO) process. The LLO process refers to a process of separating a temporary substrate below the first substrate 101 and the first substrate 101 using laser during the manufacturing process of a display device 100. Accordingly, the first substrate 101 is a layer for more easily performing the LLO process so that it is referred to as a functional thin film, a functional thin film layer, or a functional substrate.

The first substrate 101 includes an active area AA and a non-active area NA.

The active area AA is an area where images are displayed. In the active area AA, a pixel unit PD configured by a plurality of sub pixels may be disposed to display images. For example, the pixel unit PD is configured by a plurality of sub pixels including a light emitting diode and a driving circuit to display images.

The non-active area NA is an area where no image is displayed and various wiring lines and driving ICs for driving the sub pixels disposed in the active area AA are disposed. For example, in the non-active area NA, various driving ICs, such as a gate driver IC and a data driver IC, may be disposed.

The plurality of flexible films 170 is disposed at one end of the first substrate 101. The plurality of flexible films 170 is electrically connected to one end of the first substrate 101. The plurality of flexible films 170 is films in which various components are disposed on a base film having malleability to supply a signal to the plurality of sub pixels of the active area AA. One ends of the plurality of flexible films 170 are disposed in the non-active area NA of the first substrate 101 to supply a data voltage to the plurality of sub pixels of the active area AA. In the meantime, even though four flexible films 170 are illustrated in FIG. 1, the number of flexible films 170 may vary depending on the design, but is not limited thereto.

In the meantime, a driving IC, such as a gate driver IC or a data driver IC, may be disposed on the plurality of flexible films 170. The driving IC is a component which processes data for displaying images and a driving signal for processing the data. The driving IC may be disposed by a chip on glass (COG), a chip on film (COF), or a tape carrier package (TCP) technique depending on a mounting method. In the present specification, for the convenience of description, it is described that the driving IC is mounted on the plurality of flexible films 170 by a chip on film technique, but is not limited thereto.

The printed circuit board 180 is connected to the plurality of flexible films 170. The printed circuit board 180 is a component which supplies signals to the driving IC. Various components may be disposed in the printed circuit board 180 to supply various driving signals such as a driving signal or a data voltage to the driving IC. In the meantime, even though two printed circuit boards 180 are illustrated in FIG. 1, the number of printed circuit boards 180 may vary depending on the design and is not limited thereto.

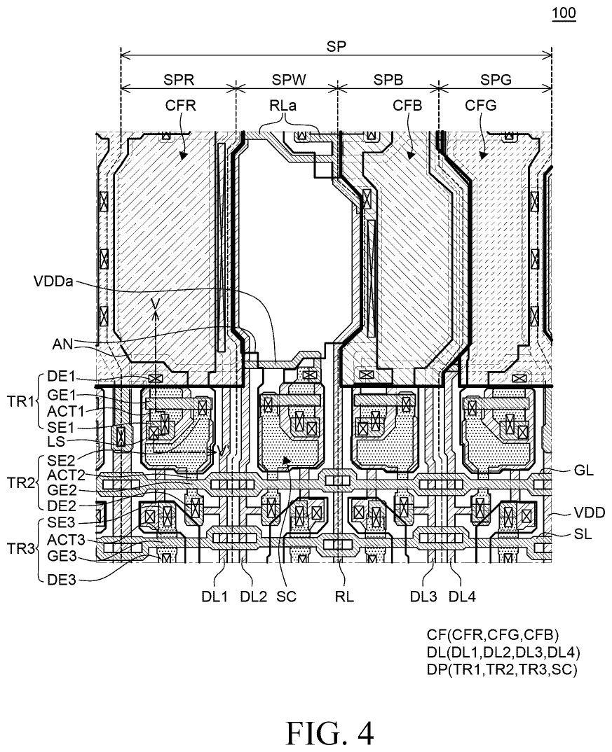

Referring to FIG. 2, an inorganic layer 110 is disposed on the first substrate 101. The inorganic layer 110 may be a plurality of inorganic layers including a lower buffer layer 111, an upper buffer layer 112, a gate insulating layer 113, and a passivation layer 114 to be described below. The inorganic layer 110 will be described in more detail below with reference to FIGS. 4 to 6C.

The planarization layer 120 and the bank 130 are disposed on the inorganic layer 110. Specifically, the planarization layer 120 is disposed so as to enclose a top surface and a side surface of the inorganic layer 110 in the non-active area NA of the first substrate 101. Further, heights of the planarization layer 120 and the bank 130 disposed in the active area AA and the non-active area NA adjacent to the active area AA and heights of the planarization layer 120 and the bank 130 disposed in the non-active area NA adjacent to an outer peripheral portion of the display device 100 may be different. The planarization layer 120 and the bank 130 will be described in more detail below with reference to FIGS. 4 to 7C.

The pixel unit PD is disposed on the inorganic layer 110. The pixel unit PD may be disposed so as to correspond to the active area AA. The pixel unit PD is a component which includes a plurality of sub pixels to display images. The plurality of sub pixels of the pixel unit PD is minimum units which configure the active area AA and a light emitting diode and a driving circuit may be disposed in each of the plurality of sub pixels. For example, the light emitting diode of each of the plurality of sub pixels may include an organic light emitting diode including an anode, an organic emission layer, and a cathode or an LED including an N-type and a P-type semiconductor layers and an emission layer, but is not limited thereto. The driving circuit for driving the plurality of sub pixels may include a driving element such as a thin film transistor or a storage capacitor, but is not limited thereto. Hereinafter, for the convenience of description, it is assumed that the light emitting diode of each of the plurality of sub pixels is an organic light emitting diode, but it is not limited thereto.

In the meantime, the display device 100 may be configured by a top emission type or a bottom emission type, depending on an emission direction of light which is emitted from the light emitting diode.

According to the top emission type, light emitted from the light emitting diode is emitted to an upper portion of the first substrate 101 on which the light emitting diode is disposed. In the case of the top emission type, a reflective layer may be formed below the anode to allow the light emitted from the organic light emitting diode to travel to the upper portion of the first substrate 101, that is, toward the cathode.

According to the bottom emission type, light emitted from the light emitting diode is emitted to a lower portion of the first substrate 101 on which the light emitting diode is disposed. In the case of the bottom emission type, the anode may be formed only of a transparent conductive material and the cathode may be formed of the metal material having a high reflectance to allow the light emitted from the light emitting diode to travel to the lower portion of the first substrate 101.

Hereinafter, for the convenience of description, the description will be made by assuming that the display device 100 according to an exemplary embodiment of the present disclosure is a bottom emission type display device, but it is not limited thereto.

The adhesive layer 140 is disposed so as to cover the pixel unit PD. Further, the adhesive layer 140 serves to bond the first substrate 101 and a second substrate 150 and encloses the pixel unit PD to protect the light emitting diode of the pixel unit PD from external moisture, oxygen, and impacts. The adhesive layer 140 may be configured by a face seal type. For example, the adhesive layer 140 may be formed by forming ultraviolet or thermosetting sealant on the entire surface of the pixel unit PD. However, the structure of the adhesive layer 140 may be formed by various methods and materials, but is not limited thereto.

In the meantime, the second substrate 150 which has a high modulus and is formed of a metal material having a strong corrosion resistance is disposed on the adhesive layer 140. For example, the second substrate 150 may be formed of a material having a high modulus of approximately 200 to 900 MPa. The second substrate may be formed of a metal material, which has a high corrosion resistance and is easily processed in the form of a foil or a thin film, such as aluminum (Al), nickel (Ni), chromium (Cr), iron (Fe), and an alloy material of nickel. Therefore, as the second substrate 150 is formed of a metal material, the second substrate 150 may be implemented as an ultra-thin film and provide a strong resistance against external impacts and scratches.

An end of the second substrate 150 is disposed inside the first substrate 101 and disposed outside more than the end of the inorganic layer 110.

A polarizer 160 is disposed below the first substrate 101. The polarizer 160 selectively transmits light to reduce the reflection of external light which is incident onto the first substrate 101. Specifically, in the display device 100, various metal materials which are applied to semiconductor devices, wiring lines, and light emitting diodes are formed on the first substrate 101. Therefore, the external light incident onto the first substrate 101 may be reflected from the metal material so that the visibility of the display device 100 may be reduced due to the reflection of the external light. At this time, the polarizer 160 which suppresses the reflection of external light is disposed below the first substrate 101 to increase outdoor visibility of the display device 100. However, the polarizer 160 may be omitted depending on an implementation example of the display device 100.

Even though not illustrated in the drawing, a barrier film may be disposed below the first substrate 101 together with the polarizer 160. The barrier film reduces the permeation of the moisture and oxygen outside the first substrate 101 into the first substrate 101 to protect the pixel unit PD including a light emitting diode. However, the barrier film may be omitted depending on an implementation example of the display device 100, but it is not limited thereto.

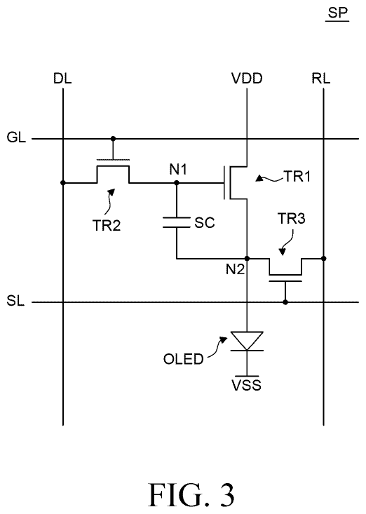

Hereinafter, the plurality of sub pixels of the pixel unit PD will be described in more detail with reference to FIGS. 3 to 7C.

FIG. 3 is a circuit diagram of a sub pixel of a display device according to an exemplary embodiment of the present disclosure.

Referring to FIG. 3, the driving circuit for driving the light emitting diode OLED of the plurality of sub pixels SP includes a first transistor TR1, a second transistor TR2, a third transistor TR3, and a storage capacitor SC. In order to drive the driving circuit, a plurality of wiring lines including a gate line GL, a data line DL, a high potential power line VDD, a sensing line SL, and a reference line RL is disposed on the first substrate 101.

Each of the first transistor TR1, the second transistor TR2, and the third transistor TR3 included in the driving circuit of one sub pixel SP includes a gate electrode, a source electrode, and a drain electrode.

The first transistor TR1, the second transistor TR2, and the third transistor TR3 may be P-type thin film transistors or N-type thin film transistors. For example, since in the P-type thin film transistor, holes flow from the source electrode to the drain electrode, the current flows from the source electrode to the drain electrode. Since in the N-type thin film transistor, electrons flow from the source electrode to the drain electrode, the current flows from the drain electrode to the source electrode. Hereinafter, the description will be made under the assumption that the first transistor TR1, the second transistor TR2, and the third transistor TR3 are N-type thin film transistors in which the current flows from the drain electrode to the source electrode, but the present disclosure is not limited thereto.

The first transistor TR1 includes a first active layer, a first gate electrode, a first source electrode, and a first drain electrode. The first gate electrode is connected to a first node N1, the first source electrode is connected to the anode of the light emitting diode OLED, and the first drain electrode is connected to the high potential power line VDD. When a voltage of the first node N1 is higher than a threshold voltage, the first transistor TR1 is turned on and when the voltage of the first node N1 is lower than the threshold voltage, the first transistor TR1 is turned off. When the first transistor TR1 is turned on, a driving current may be transmitted to the light emitting diode OLED by means of the first transistor TR1. Therefore, the first transistor TR1 which controls the driving current transmitted to the light emitting diode OLED may be referred to as a driving transistor.

The second transistor TR2 includes a second active layer, a second gate electrode, a second source electrode, and a second drain electrode. The second gate electrode is connected to the gate line GL, the second source electrode is connected to the first node N1, and the second drain electrode is connected to the data line DL. The second transistor TR2 may be turned on or off based on a gate voltage from the gate line GL. When the second transistor TR2 is turned on, a data voltage from the data line DL may be charged in the first node N1. Therefore, the second transistor TR2 which is turned on or turned off by the gate line GL may also be referred to as a switching transistor.

The third transistor TR3 includes a third active layer, a third gate electrode, a third source electrode, and a third drain electrode. The third gate electrode is connected to the sensing line SL, the third source electrode is connected to the second node N2, and the third drain electrode is connected to the reference line RL. The third transistor TR3 may be turned on or off based on a sensing voltage from the sensing line SL. When the third transistor TR3 is turned on, a reference voltage from the reference line RL may be transmitted to the second node N2 and the storage capacitor SC. Therefore, the third transistor TR3 may also be referred to as a sensing transistor.

In the meantime, even though in FIG. 3, it is illustrated that the gate line GL and the sensing line SL are separate wiring lines, the gate line GL and the sensing line SL may be implemented as one wiring line, but it is not limited thereto.

The storage capacitor SC is connected between the first gate electrode and the first source electrode of the first transistor TR1. That is, the storage capacitor SC may be connected between the first node N1 and the second node N2. The storage capacitor SC maintains a potential difference between the first gate electrode and the first source electrode of the first transistor TR1 while the light emitting diode OLED emits light, so that a constant driving current may be supplied to the light emitting diode OLED. The storage capacitor SC includes a plurality of capacitor electrodes and for example, one of a plurality of capacitor electrodes is connected to the first node N1 and the other one is connected to the second node N2.

The light emitting diode OLED includes an anode, an emission layer, and a cathode. The anode of the light emitting diode OLED is connected to the second node N2 and the cathode is connected to the low potential power line VSS. The light emitting diode OLED is supplied with a driving current from the first transistor TR1 to emit light.

In the meantime, in FIG. 3, it is described that the driving circuit of the sub pixel SP of the display device 100 according to the exemplary embodiment of the present disclosure has a 3T1C structure including three transistors and one storage capacitor SC. However, the number and a connection relationship of the transistors and the storage capacitor may vary in various ways depending on the design and are not limited thereto.

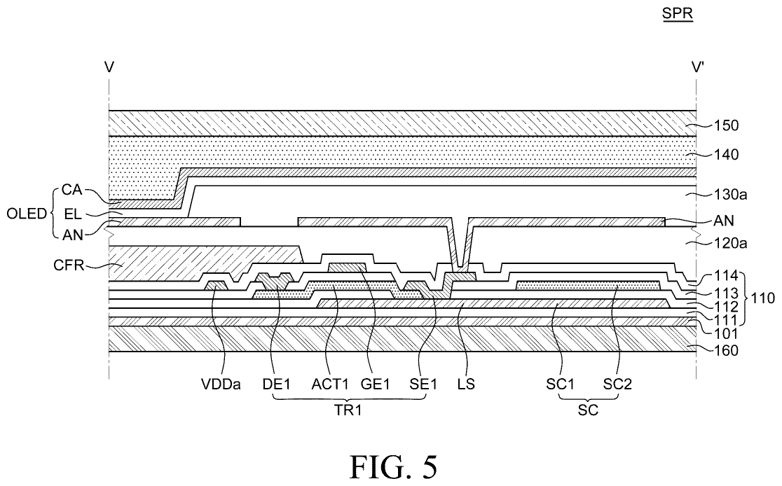

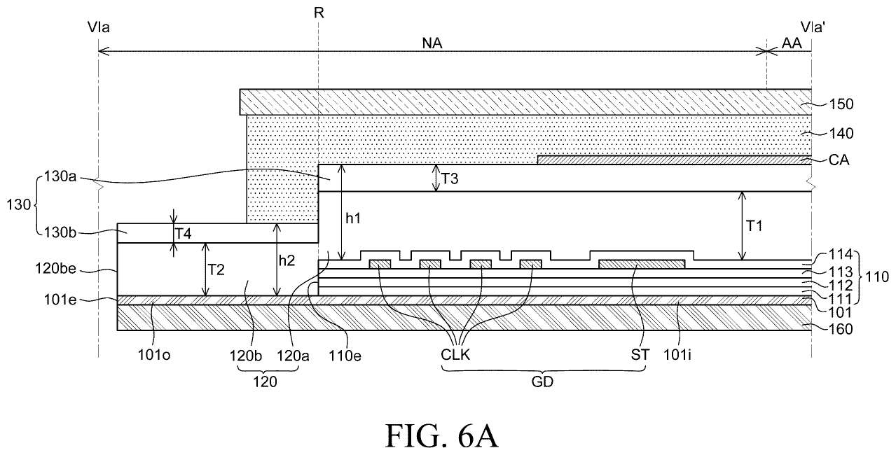

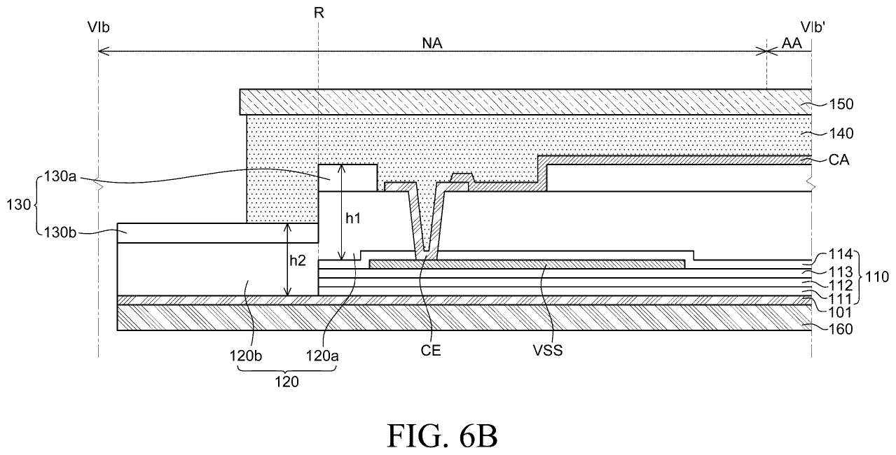

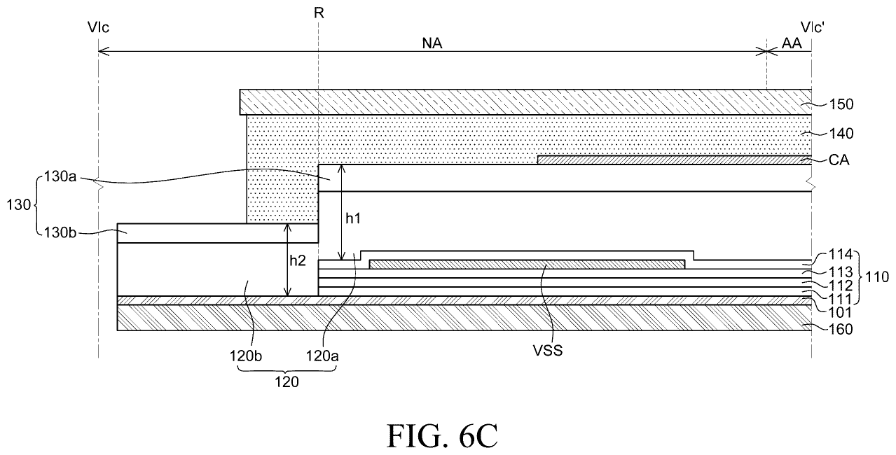

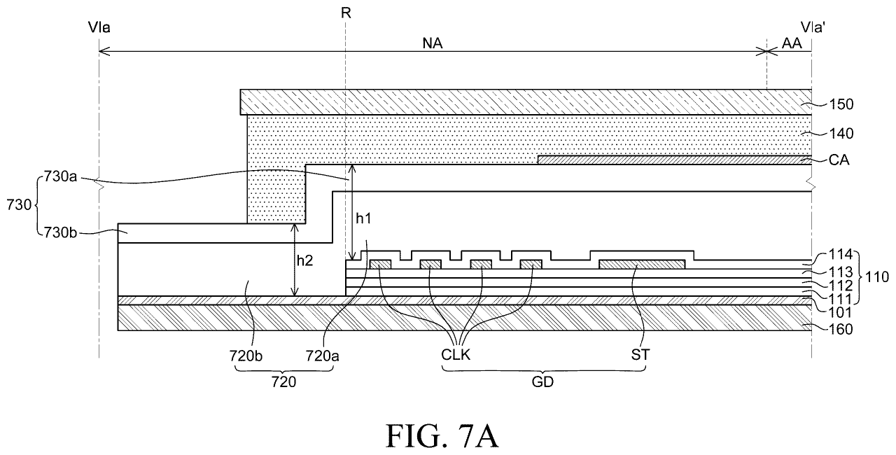

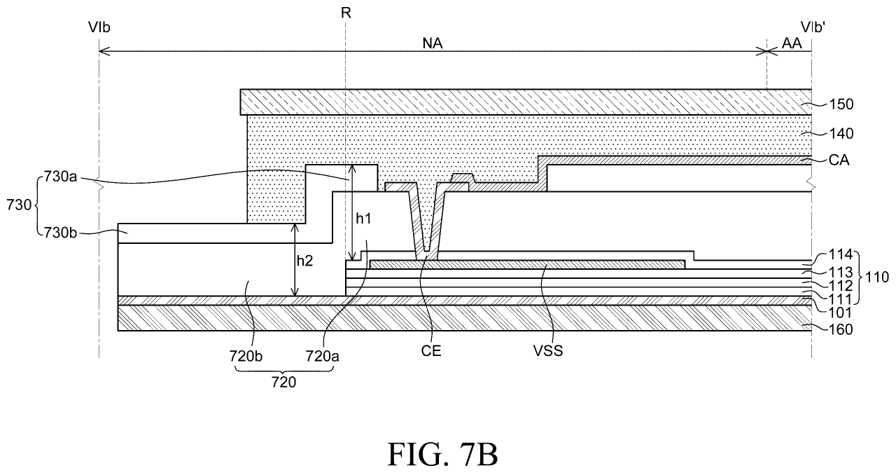

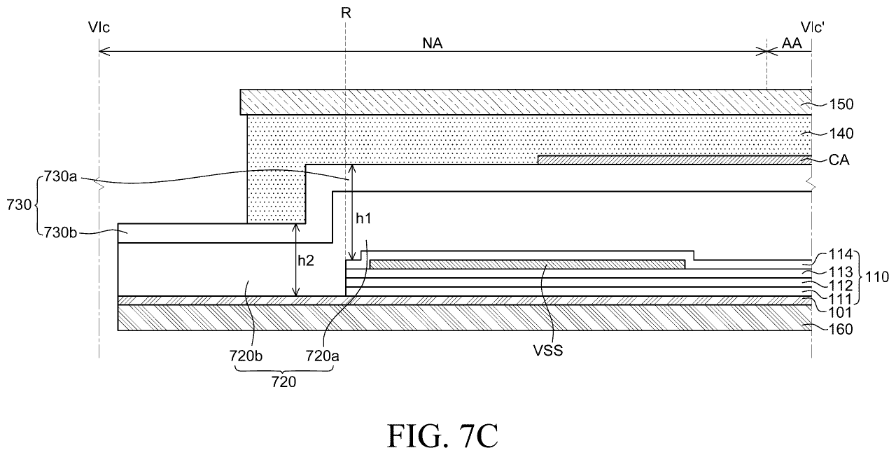

FIG. 4 is an enlarged plan view of one pixel of a display device according to an exemplary embodiment of the present disclosure. FIG. 5 is a cross-sectional view taken along the line V-V′ of FIG. 4. FIG. 6A is a cross-sectional view of a first exemplary embodiment taken along the line VIa-VIa′ of FIG. 1. FIG. 6B is a cross-sectional view of a first exemplary embodiment taken along VIb-VIb′ of FIG. 1. FIG. 6C is a cross-sectional view of a first exemplary embodiment taken along VIc-VIc′ of FIG. 1. FIG. 7A is a cross-sectional view of a second exemplary embodiment taken along the line VIa-VIa′ of FIG. 1. FIG. 7B is a cross-sectional view of a second exemplary embodiment taken along VIb-VIb′ of FIG. 1. FIG. 7C is a cross-sectional view of a second exemplary embodiment taken along VIc-VIc′ of FIG. 1. FIG. 4 is an enlarged plan view of a red sub pixel SPR, a white sub pixel SPW, a blue sub pixel SPB, and a green sub pixel SPG which configure one pixel disposed in the active area AA of the display panel 120. In FIG. 4, only the sub pixel SP of the display device 100 is illustrated and for the convenience of description, the bank 130 is omitted and edges of the plurality of color filters CF are illustrated with a bold solid line.

Referring to FIGS. 4 to 7C, the display device 100 according to the exemplary embodiment of the present disclosure includes a first substrate 101, an inorganic layer 110, a planarization layer 120, a bank 130, a first transistor TR1, a second transistor TR2, a third transistor TR3, a storage capacitor SC, a light emitting diode OLED, a gate line GL, a sensing line SL, a data line DL, a reference line RL, a high potential power line VDD, a plurality of color filters CF, an adhesive layer 140, a second substrate 150, and a polarizer 180.

Referring to FIG. 4, the plurality of sub pixels SP includes a red sub pixel SPR, a green sub pixel SPG, a blue sub pixel SPB, and a white sub pixel SPW. For example, the red sub pixel SPR, the white sub pixel SPW, the blue sub pixel SPB, and the green sub pixel SPG may be sequentially disposed along a row direction. However, the placement order of the plurality of sub pixels SP is not limited thereto.

Each of the plurality of sub pixels SP includes an emission area and a circuit area. The emission area is an area where one color light is independently emitted and the light emitting diode OLED may be disposed therein. Specifically, in an area where the plurality of color filters CF and the anode AN overlap, an area which is exposed from the bank 130 to allow light emitted from the light emitting diode OLED to travel to the outside is defined as an emission area. For example, referring to FIGS. 4 and 5 together, an emission area of the red sub pixel SPR is an area exposed from the bank 130 in an area in which the red color filter CFR and the anode AN overlap. An emission area of the green sub pixel SPG is an area exposed from the bank 130 in an area in which the green color filter CFG and the anode AN overlap. An emission area of the blue sub pixel SPB is an area exposed from the bank 130 in an area in which the blue color filter CFB and the anode AN overlap. At this time, in an emission area of the white sub pixel SPW in which a separate color filter CF is not disposed, an area overlapping a part of the anode AN exposed from the bank 130 may be a white emission area which emits white light.

The circuit area is an area excluding the emission area and a driving circuit DP for driving the plurality of light emitting diodes OLED and a plurality of wiring lines which transmits various signals to the driving circuit DP may be disposed. The circuit area in which the driving circuit DP, the plurality of wiring lines, and the bank 130 are disposed may be a non-emission area. For example, in the circuit area, the driving circuit DP including the first transistor TR1, the second transistor TR2, the third transistor TR3, and the storage capacitor SC, a plurality of high potential power lines VDD, a plurality of data lines DL, a plurality of reference lines RL, a plurality of gate lines GL, a sensing line SL, and the bank 124 are disposed.

Referring to FIGS. 3 to 7C together, an inorganic layer 110 is disposed on the first substrate 101. The inorganic layer 110 may include a plurality of layers configured by an inorganic material disposed on the first substrate 101. For example, the inorganic layer 110 may include a lower buffer layer 111, an upper buffer layer 112, a gate insulating layer 113, and a passivation layer 114, but is not limited thereto.

The inorganic layer 110 is disposed on an inside portion 101i so as to expose an outermost or edge area 1010 of the first substrate 101 in the non-active area NA. In some implementations, the edge portion 101e is outside of the inside portion 101i. For example, an end 110e of the inorganic layer 110 may be disposed in the inside of the end 101e of the first substrate 101.

In the meantime, when the first substrate 101 configured by one of the transparent conducting oxide layer or the oxide semiconductor is used as described above, the first substrate 101 may be disposed in the entire area of the display device 100 for the LLO process. That is, the first substrate 101 may be disposed in the entire active area AA and non-active area NA of the display device 100.

Referring to FIGS. 6A to 7C, the inorganic layer 110 of the display device 100 according to the exemplary embodiment of the present disclosure may be disposed to a reference line R of the non-active area NA so as to expose an outermost area 1010 of the first substrate 101. Here, the reference line R defines an end position of the inorganic layer 110 and is located in the non-active area NA between the non-active area NA adjacent to the active area AA and an outermost area of the first substrate 101. Therefore, the crack of the inorganic layer 110 which is exposed to the outermost area or moisture permeation through the inorganic layer 110 may be reduced.

The inorganic layer 110 may include multiple layers. For example, the inorganic layer 110 may include a lower buffer layer 111 disposed on the first substrate 101. The lower buffer layer 111 suppresses moisture and/or oxygen which penetrates from the outside of the first substrate 101 from being spread. The moisture permeation characteristic of the display device 100 may be controlled by controlling a thickness or a lamination structure of the lower buffer layer 111. Further, the lower buffer layer 111 may suppress a short-circuit defect from being caused when the first substrate 101 formed of a transparent conducting oxide or an oxide semiconductor is in contact with the other configurations such as the pixel unit PD. The lower buffer layer 111 may be formed of an inorganic material, for example, may be configured by a single layer or a double layer of silicon oxide SiOx and silicon nitride SiNx, but is not limited thereto.

The plurality of high potential power lines VDD, the plurality of data lines DL, the plurality of reference lines RL, and the light shielding layer LS are disposed on the lower buffer layer 111.

The plurality of high potential power lines VDD, the plurality of data lines DL, the plurality of reference lines RL, and the light shielding layer LS are disposed on the same layer on the first substrate 101 and are formed of the same conductive material. For example, the plurality of high potential power lines VDD, the plurality of data lines DL, the plurality of reference lines RL, and the light shielding layer LS may be configured by a conductive material, such as copper (Cu), aluminum (Al), molybdenum (Mo), nickel (Ni), titanium (Ti), chrome (Cr), or an alloy thereof, but are not limited thereto.

The plurality of high potential power lines VDD is wiring lines which transmit the high potential power signal to each of the plurality of sub pixels SP. The plurality of high potential power lines VDD extends between the plurality of sub pixels SP in a column direction and two sub pixels SP which are adjacent to each other in the row direction may share one high potential power line VDD among the plurality of high potential power lines VDD. For example, one high potential power line VDD is disposed at a left side of the red sub pixel SPR to supply a high potential power voltage to the first transistor TR1 of each of the red sub pixel SPR and the white sub pixel SPW. The other high potential power line VDD is disposed at a right side of the green sub pixel SPG to supply a high potential power voltage to the first transistor TR1 of each of the blue sub pixel SPB and the green sub pixel SPG.

The plurality of data lines DL is lines which extend between the plurality of sub pixels SP in a column direction to transmit a data voltage to each of the plurality of sub pixels SP and includes a first data line DL1, a second data line DL2, a third data line DL3, and a fourth data line DL4. The first data line DL1 is disposed between the red sub pixel SPR and the white sub pixel SPW to transmit a data voltage to the second transistor TR2 of the red sub pixel SPR. The second data line DL2 is disposed between the first data line DL1 and the white sub pixel SPW to transmit the data voltage to the second transistor TR2 of the white sub pixel SPW. The third data line DL3 is disposed between the blue sub pixel SPB and the green sub pixel SPG to transmit a data voltage to the second transistor TR2 of the blue sub pixel SPB. The fourth data line DL4 is disposed between the third data line DL3 and the green sub pixel SPG to transmit the data voltage to the second transistor TR2 of the green sub pixel SPG.

The plurality of reference lines RL extends between the plurality of sub pixels SP in the column direction to transmit a reference voltage to each of the plurality of sub pixels SP. The plurality of sub pixels SP which forms one pixel may share one reference line RL. For example, one reference line RL is disposed between the white sub pixel SPW and the blue sub pixel SPB to transmit a reference voltage to a third transistor TR3 of each of the red sub pixel SPR, the white sub pixel SPW, the blue sub pixel SPB, and the green sub pixel SPG.

Referring to FIGS. 4 and 5 together, a light shielding layer LS is disposed on the lower buffer layer 111. The light shielding layer LS is disposed so as to overlap the first active layer ACT1 of at least the first transistor TR1 among the plurality of transistors TR1, TR2, and TR3 to block light incident onto the first active layer ACT1. If light is irradiated onto the first active layer ACT1, a leakage current is generated so that the reliability of the first transistor TR1 which is a driving transistor may be degraded. At this time, if the light shielding layer LS configured by an opaque conductive material such as copper (Cu), aluminum (Al), molybdenum (Mo), nickel (Ni), titanium (Ti), chrome (Cr), or an alloy thereof is disposed so as to overlap the first active layer ACT1, light incident from the lower portion of the first substrate 101 onto the first active layer ACT1 may be blocked. Accordingly, the reliability of the first transistor TR1 may be improved. However, it is not limited thereto and the light shielding layer LS may be disposed so as to overlap the second active layer ACT2 of the second transistor TR2 and the third active layer ACT3 of the third transistor TR3.

In the meantime, even though in the drawing, it is illustrated that the light single layer LS is a single layer, the light shielding layer LS may be formed as a plurality of layers. For example, the light shielding layer LS may be formed between the inorganic layers 110, that is, formed of a plurality of layers disposed so as to overlap each other, with at least one of the lower buffer layer 111, the upper buffer layer 112, the gate insulating layer 113, and the passivation layer 114 therebetween.

The inorganic layer 110 may also include an upper buffer layer 112 disposed on the plurality of high potential power lines VDD, the plurality of data lines DL, the plurality of reference lines RL, and the light shielding layer LS. The upper buffer layer 112 may reduce permeation of moisture or impurities through the first substrate 101. For example, the upper buffer layer 112 may be configured by a single layer or a double layer of silicon oxide SiOx or silicon nitride SiNx, but is not limited thereto. Further, the upper buffer layer 112 may be omitted depending on a type of first substrate 101 or a type of transistor, but is not limited thereto.

In each of the plurality of sub pixels SP, the first transistor TR1, the second transistor TR2, the third transistor TR3, and the storage capacitor SC are disposed on the upper buffer layer 112.

First, the first transistor TR1 includes a first active layer ACT1, a first gate electrode GE1, a first source electrode SE1, and a first drain electrode DE1.

The first active layer ACT1 is disposed on the upper buffer layer 112. The first active layer ACT1 may be formed of a semiconductor material such as an oxide semiconductor, amorphous silicon, or polysilicon, but is not limited thereto. For example, when the first active layer ACT1 is formed of an oxide semiconductor, the first active layer ACT1 is formed by a channel region, a source region, and a drain region and the source region and the drain region may be conductive regions, but are not limited thereto.

The gate insulating layer 113 is disposed on the first active layer ACT1. The gate insulating layer 113 is a layer for electrically insulating the first gate electrode GE1 from the first active layer ACT1 and may be formed of an insulating material. For example, the gate insulating layer 113 may be configured by a single layer or a double layer of silicon oxide SiOx or silicon nitride SiNx, but is not limited thereto.

The first gate electrode GE1 is disposed on the gate insulating layer 113 so as to overlap the first active layer ACT1. The first gate electrode GE1 may be configured by a conductive material such as copper (Cu), aluminum (Al), molybdenum (Mo), nickel (Ni), titanium (Ti), chrome (Cr), or an alloy thereof, but is not limited thereto.

A first source electrode SE1 and a first drain electrode DE1 which are spaced apart from each other are disposed on the gate insulating layer 113. The first source electrode SE1 and the first drain electrode DE1 may be electrically connected to the first active layer ACT1 through a contact hole formed on the gate insulating layer 113. The first source electrode SE1 and the first drain electrode DE1 may be disposed on the same layer as the first gate electrode GE1 to be formed of the same conductive material, but are not limited thereto. For example, the first source electrode SE1 and the first drain electrode DE1 may be configured by copper (Cu), aluminum (Al), molybdenum (Mo), nickel (Ni), titanium (Ti), chrome (Cr), or an alloy thereof, but is not limited thereto.

The first drain electrode DE1 is electrically connected to the high potential power lines VDD. For example, the first drain electrodes DE1 of the red sub pixel SPR and the white sub pixel SPW may be electrically connected to the high potential power line VDD at the left side of the red sub pixel SPR. The first drain electrodes DE1 of the blue sub pixel SPB and the green sub pixel SPG may be electrically connected to the high potential power line VDD at the right side of the green sub pixel SPG.

At this time, an auxiliary high potential power line VDDa may be further disposed to electrically connect the first drain electrode DE1 with the high potential power line VDD. One end of the auxiliary high potential power line VDDa is electrically connected to the high potential power line VDD and the other end is electrically connected to the first drain electrode DE1 of each of the plurality of sub pixels SP. For example, when the auxiliary high potential power line VDDa is formed of the same material on the same layer as the first drain electrode DE1, one end of the auxiliary high potential power line VDDa is electrically connected to the high potential power line VDD through a contact hole formed in the gate insulating layer 113 and the upper buffer layer 112. The other end of the auxiliary high potential power line VDDa extends to the first drain electrode DE1 to be integrally formed with the first drain electrode DE1.

At this time, the first drain electrode DE1 of the red sub pixel SPR and the first drain electrode DE1 of the white sub pixel SPW which are electrically connected to the same high potential power lines VDD may be connected to the same auxiliary high potential power line VDDa. The first drain electrode DE1 of the blue sub pixel SPB and the first drain electrode DE1 of the green sub pixel SPG may also be connected to the same auxiliary high potential power line VDDa. However, the first drain electrode DE and the high potential power line VDD may be electrically connected by another method, but it is not limited thereto.

The first source electrode SE1 may be electrically connected to the light shielding layer LS through a contact hole formed in the gate insulating layer 113 and the upper buffer layer 112. Further, a part of the first active layer ACT1 connected to the first source electrode SE1 may be electrically connected to the light shielding layer LS through a contact hole formed on and the upper buffer layer 112. If the light shielding layer LS is floated, a threshold voltage of the first transistor TR1 fluctuates to affect the driving of the display device 100. Accordingly, the light shielding layer LS is electrically connected to the first source electrode SE1 to apply a voltage to the light shielding layer LS and it does not affect the driving of the first transistor TR1. However, in the present specification, even though it has been described that both the first active layer ACT1 and the first source electrode SE1 are in contact with the light shielding layer LS, only any one of the first source electrode SE1 and the first active layer ACT1 is in direct contact with the light shielding layer LS, but it is not limited thereto.

In the meantime, even though in FIG. 5, it is illustrated that the gate insulating layer 113 is formed on the entire surface of the first substrate 101, the gate insulating layer 113 may be patterned so as to overlap only the first gate electrode GE1, the first source electrode SE1, and the first drain electrode DE1, but is not limited thereto.

The second transistor TR2 includes a second active layer ACT2, a second gate electrode GE2, a second source electrode SE2, and a second drain electrode DE2.

The second active layer ACT2 is disposed on the upper buffer layer 112. The second active layer ACT2 may be formed of a semiconductor material, such as an oxide semiconductor, amorphous silicon, or polysilicon, but is not limited thereto. For example, when the second active layer ACT2 is formed of an oxide semiconductor, the second active layer ACT2 may be formed by a channel region, a source region, and a drain region and the source region and the drain region may be conductive regions, but are not limited thereto.

The second source electrode SE2 is disposed on the upper buffer layer 112. The second source electrode SE2 may be integrally formed with the second active layer ACT2 to be electrically connected to each other. For example, the semiconductor material is formed on the upper buffer layer 112 and a part of the semiconductor material is conducted to form the second source electrode SE2. Therefore, a part of the semiconductor material which is not conducted may become a second active layer ACT2 and a conducted part serves as a second source electrode SE2. However, the second active layer ACT2 and the second source electrode SE2 are separately formed, but are not limited thereto.

The second source electrode SE2 is electrically connected to the first gate electrode GE1 of the first transistor TR1. The first gate electrode GE1 may be electrically connected to the second source electrode SE2 through a contact hole formed on the gate insulating layer 113. Accordingly, the first transistor TR1 may be turned on or turned off by a signal from the second transistor TR2.

The gate insulating layer 113 is disposed on the second active layer ACT2 and the second source electrode SE2 and the second drain electrode DE2 and the second gate electrode GE2 are disposed on the gate insulating layer 113.

The second gate electrode GE2 is disposed on the gate insulating layer 113 so as to overlap the second active layer ACT2. The second gate electrode GE2 may be electrically connected to the gate line GL and the second transistor TR2 may be turned on or turned off based on the gate voltage transmitted to the second gate electrode GE2. The second gate electrode GE2 may be configured by a conductive material such as copper (Cu), aluminum (Al), molybdenum (Mo), nickel (Ni), titanium (Ti), chrome (Cr), or an alloy thereof, but is not limited thereto.

In the meantime, the second gate electrode GE2 extends from the gate line GL. That is, the second gate electrode GE2 is integrally formed with the gate line GL and the second gate electrode GE2 and the gate line GL may be formed of the same conductive material. For example, the gate line GL may be configured by copper (Cu), aluminum (Al), molybdenum (Mo), nickel (Ni), titanium (Ti), chrome (Cr), or an alloy thereof, but is not limited thereto.

The gate line GL is a wiring line which transmits the gate voltage to each of the plurality of sub pixels SP and extends in the row direction while crossing the circuit area of the plurality of sub pixels SP. The gate line GL extends in the row direction to intersect the plurality of high potential power lines VDD, the plurality of data lines DL, and the plurality of reference lines RL extending in the column direction.

The second drain electrode DE2 is disposed on the gate insulating layer 113. The second drain electrode DE2 is electrically connected to the second active layer ACT2 through a contact hole formed in the gate insulating layer 113 and is electrically connected to one of the plurality of data lines DL through a contact hole formed in the gate insulating layer 113 and the upper buffer layer 112, simultaneously. For example, the second drain electrode DE2 of the red sub pixel SPR is electrically connected to the first data line DL1 and the second drain electrode DE2 of the white sub pixel SPW is electrically connected to the second data line DL2. For example, the second drain electrode DE2 of the blue sub pixel SPB is electrically connected to the third data line DL3 and the second drain electrode DE2 of the green sub pixel SPG is electrically connected to the fourth data line DL4. The second drain electrode DE2 may be configured by a conductive material, such as copper (Cu), aluminum (Al), molybdenum (Mo), nickel (Ni), titanium (Ti), chrome (Cr), or an alloy thereof, but is not limited thereto. The third transistor TR3 includes a third active layer ACT3, a third gate electrode GE3, a third source electrode SE3, and a third drain electrode DE3.

The third active layer ACT3 is disposed on the upper buffer layer 112. The third active layer ACT3 may be formed of a semiconductor material, such as an oxide semiconductor, amorphous silicon, or polysilicon, but is not limited thereto. For example, when the third active layer ACT3 is formed of an oxide semiconductor, the third active layer ACT3 is formed by a channel region, a source region, and a drain region and the source region and the drain region may be conductive regions, but are not limited thereto.

The gate insulating layer 113 is disposed on the third active layer ACT3 and the third gate electrode GE3, the third source electrode SE3, and the third drain electrode DE3 are disposed on the gate insulating layer 113.

The third gate electrode GE3 is disposed on the gate insulating layer 113 so as to overlap the third active layer ACT3. The third gate electrode GE3 is electrically connected to the sensing line SL and the third transistor TR3 may be turned on or turned off based on the sensing voltage transmitted to the third transistor TR3. The third gate electrode GE3 may be configured by a conductive material such as copper (Cu), aluminum (Al), molybdenum (Mo), nickel (Ni), titanium (Ti), chrome (Cr), or an alloy thereof, but is not limited thereto.

In the meantime, the third gate electrode GE3 extends from the sensing line SL. That is, the third gate electrode GE3 is integrally formed with the sensing line SL and the third gate electrode GE3 and the sensing line SL may be formed of the same conductive material. For example, the sensing line SL may be configured by copper (Cu), aluminum (Al), molybdenum (Mo), nickel (Ni), titanium (Ti), chrome (Cr), or an alloy thereof, but is not limited thereto.

The sensing line SL transmits a sensing voltage to each of the plurality of sub pixels SP and extends in a row direction between the plurality of sub pixels SP. For example, the sensing line SL extends in the row direction at a boundary between the plurality of sub pixels SP to intersect the plurality of high potential power lines VDD, the plurality of data lines DL, and the plurality of reference lines RL extending in the column direction.

The third source electrode SE3 may be electrically connected to the third active layer ACT3 through a contact hole formed on the gate insulating layer 113. The third source electrode SE3 may be configured by a conductive material, such as copper (Cu), aluminum (Al), molybdenum (Mo), nickel (Ni), titanium (Ti), chrome (Cr), or an alloy thereof, but is not limited thereto.

Further, a part of the third active layer ACT3 which is in contact with the third source electrode SE3 may be electrically connected to the light shielding layer LS through a contact hole formed in the upper buffer layer 112. That is, the third source electrode SE3 may be electrically connected to the light shielding layer LS with the third active layer ACT3 therebetween. Therefore, the third source electrode SE3 and the first source electrode SE1 may be electrically connected to each other by means of the light shielding layer LS.

The third drain electrode DE3 may be electrically connected to the third active layer ACT3 through a contact hole formed on the gate insulating layer 113. The third drain electrode DE3 may be configured by a conductive material such as copper (Cu), aluminum (Al), molybdenum (Mo), nickel (Ni), titanium (Ti), chrome (Cr), or an alloy thereof, but is not limited thereto.

The third drain electrode DE3 is electrically connected to the reference line RL. For example, the third drain electrodes DE3 of the red sub pixel SPR, the white sub pixel SPW, the blue sub pixel SPB, and the green sub pixel SPG may be electrically connected to the same reference line RL. That is, the plurality of sub pixels SP which forms one pixel may share one reference line RL.

At this time, an auxiliary reference line RLa may be disposed to transmit the reference line RL extending in the column direction to the plurality of sub pixels SP which is disposed in parallel along the row direction. The auxiliary reference line RLa extends in the row direction to electrically connect the reference line RL and the third drain electrode DE3 of each of the plurality of sub pixels SP. One end of the auxiliary reference line RLa is electrically connected to the reference line RL through a contact hole formed in the upper buffer layer 112 and the gate insulating layer 113. The other end of the auxiliary reference line RLa is electrically connected to the third drain electrode DE3 of each of the plurality of sub pixels SP. In this case, the auxiliary reference line RLa is integrally formed with the third drain electrode DE3 of each of the plurality of sub pixels SP and a reference voltage from the reference line RL is transmitted to the third drain electrode DE3 by means of the auxiliary reference line RLa. However, the auxiliary reference line RLa may be separately formed from the third drain electrode DE3, but is not limited thereto.

The storage capacitor SC is disposed in the circuit area of the plurality of sub pixels SP. The storage capacitor SC may store a voltage between the first gate electrode GE1 and the first source electrode SE1 of the first transistor TR1 to allow the light emitting diode OLED to continuously maintain a constant state for one frame. The storage capacitor SC includes a first capacitor electrode SC1 and a second capacitor electrode SC2.

In each of the plurality of sub pixels SP, the first capacitor electrode SC1 is disposed between the lower buffer layer 111 and the upper buffer layer 112. The first capacitor electrode SC1 may be disposed to be the closest to the first substrate 101 among the conductive components disposed on the first substrate 101. The first capacitor electrode SC1 is integrally formed with the light shielding layer LS and is electrically connected to the first source electrode SE1 by means of the light shielding layer LS.

The upper buffer layer 112 is disposed on the first capacitor electrode SC1 and the second capacitor electrode SC2 is disposed on the upper buffer layer 112. The second capacitor electrode SC2 may be disposed so as to overlap the first capacitor electrode SC1. The second capacitor electrode SC2 is integrally formed with the second source electrode SE2 to be electrically connected to the second source electrode SE2 and the first gate electrode GE1. For example, the semiconductor material is formed on the upper buffer layer 112 and a part of the semiconductor material is conducted to form the second source electrode SE2 and the second capacitor electrode SC2. Accordingly, a part of the semiconductor material which is not conducted functions as a second active layer ACT2 and the conducted part functions as a second source electrode SE2 and the second capacitor electrode SC2. As described above, the first gate electrode GE1 is electrically connected to the second source electrode SE2 through the contact hole formed in the gate insulating layer 113. Accordingly, the second capacitor electrode SC2 is integrally formed with the second source electrode SE2 to be electrically connected to the second source electrode SE2 and the first gate electrode GE1.

In summary, the first capacitor electrode SC1 of the storage capacitor SC is integrally formed with the light shielding layer LS to be electrically connected to the light shielding layer LS, the first source electrode SE1, and the third source electrode SE3. Accordingly, the second capacitor electrode SC2 is integrally formed with the second source electrode SE2 and the second active layer ACT2 to be electrically connected to the second source electrode SE2 and the first gate electrode GE1. Accordingly, the first capacitor electrode SC1 and the second capacitor electrode SC2 which overlap with the upper buffer layer 112 therebetween constantly maintain the voltage of the first gate electrode GE1 and the first source electrode SE1 of the first transistor TR1 to maintain the constant state of the light emitting diode OLED.

Referring to FIGS. 6A, 6B, 7A, and 7B, in the non-active area NA, the low potential power line VSS and the gate driver GD are disposed on the gate insulating layer 113.

Referring to FIGS. 6A and 7A, the gate driver GD is disposed in the non-active area NA and the gate driver GD includes a clock line CLK and a stage ST.

The clock line CLK transmits a clock signal to the stage ST. Four clock lines CLK as illustrated in FIGS. 6A and 7A may transmit at least one or more clock signals having different phases to the stage ST. Even though in FIGS. 6A and 7A, it is illustrated that four clock lines CLK are used, the number of clock lines CLK is not limited thereto.

The stage ST is disposed between the active area AA and the clock line CLK to output a scan signal corresponding to the driving signal. Even though in FIGS. 6A and 7A, it is illustrated that the stage ST is a single layer, this is the convenience of description so that the stage ST may be configured by various transistors and/or capacitors.

Referring to FIGS. 6B and 7B, the low potential power line VSS is electrically connected to the cathode CA to supply a low potential voltage to the cathode CA. That is, the low potential power line VSS is electrically connected to the cathode CA through the connection electrode CE which is formed together while forming the anode AN.

The passivation layer 114 is disposed on the first transistor TR1, the second transistor TR2, the third transistor TR3, and the storage capacitor SC in the active area AA and the low potential power line VSS, the high potential power line VDD, and the gate driver GD in the non-active area NA. The passivation layer 114 is an insulating layer for protecting components below the passivation layer 114. For example, the passivation layer 114 may be configured by a single layer or a double layer of silicon oxide SiOx or silicon nitride SiNx, but is not limited thereto. Further, the passivation layer 114 may be omitted depending on the exemplary embodiment.

A plurality of color filters CF may be disposed in the emission area of each of the plurality of sub pixels SP on the passivation layer 114. As described above, the display device 100 according to the exemplary embodiment of the present disclosure is a bottom emission type in which light emitted from the light emitting diode OLED is directed to the lower portion of the light emitting diode OLED and the first substrate 101. Therefore, the plurality of color filters CF may be disposed below the light emitting diode OLED. Light emitted from the light emitting diode OLED passes through the plurality of color filters CF and is implemented as various colors of light.

The plurality of color filters CF may include a red color filter CFR, a blue color filter CFB, and a green color filter CFG. The red color filter CFR is disposed in an emission area of the red sub pixel SPR of the plurality of sub pixels SP, the blue color filter CFB is disposed in an emission area of the blue sub pixel SPB, and the green color filter CFG is disposed in an emission area of the green sub pixel SPG.

The planarization layer 120 is disposed on the passivation layer 114 and the plurality of color filters CF.

The planarization layer 120 is an insulating layer which planarizes an upper portion of the first substrate 101 on which the first transistor TR1, the second transistor TR2, the third transistor TR3, the storage capacitor SC, the plurality of high potential power lines VDD, the plurality of data lines DL, the plurality of reference lines RL, the plurality of gate lines GL, and the plurality of sensing lines SL are disposed. The planarization layer 120 is disposed on the entire surface of the first substrate 101. That is, the planarization layer 120 is not only disposed in the active area AA, but also disposed to the end of the first substrate 110 while enclosing the end of the inorganic layer 101 located in the non-active area NA. Therefore, in the display device 100 according to one exemplary embodiment of the present disclosure, the planarization layer 120 is disposed so as to cover an end of the inorganic layer 110 to reduce the damage of the inorganic layer 123.

Referring to FIGS. 6A to 6C, the planarization layer 120 includes a first planarization layer 120a and a second planarization layer 120b. In some implementations, the first planarization layer 120a and the second planarization layer 120b are arranged lateral to one another and in some implementations in contact with one another, e.g., laterally along the reference line R as an implementation shown in FIG. 6A.

The first planarization layer 120a is disposed in an area of the active area AA and the non-active area NA in which the inorganic layer 110 is disposed. That is, the first planarization layer 120a may be disposed in an area which overlaps the inorganic layer 110.

The second planarization layer 120b extends from the first planarization layer 120a and is disposed in a non-active area NA in which the inorganic layer 110 is not disposed. That is, the second planarization layer 120b may be disposed in an area which does not overlap the inorganic layer 110. An end 120be of the second planarization layer 120b is coplanar with an end 101e of the first substrate 101. The second planarization layer 120b may have a thickness T2 smaller than a thickness T1 of the first planarization layer 120a. Here, the thickness T2 of the second planarization layer 120b is adjusted by forming a planarization material on an entire surface of the first substrate 101 and then etching only an end of the inorganic layer 110, that is, an outer peripheral portion with respect to the reference line R. Therefore, a height or a thickness of the first planarization layer 120a and a height or a thickness of the second planarization layer 120b may be different from each other with respect to the first substrate 101. That is, a height or a thickness of the second planarization layer 120b disposed in an outermost area of the first substrate 101 may be smaller than a height or a thickness of the first planarization layer 120a disposed on the inorganic layer 110.

The light emitting diode OLED is disposed in an emission area of each of the plurality of sub pixels SP. The light emitting diode OLED is disposed on the planarization layer 120 in each of the plurality of sub pixels SP. The light emitting diode OLED includes an anode AN, an emission layer EL, and a cathode CA.

The anode AN is disposed on the planarization layer 120 in the emission area. The anode AN supplies holes to the emission layer EL so that the anode may be formed of a conductive material having a high work function. For example, the anode AN may be formed of a transparent conductive material such as indium tin oxide (ITO) and indium zinc oxide (IZO), but is not limited thereto.

In the meantime, the anode AN extends toward the circuit area. A part of the anode AN extends toward the first source electrode SE1 of the circuit area from the emission area and is electrically connected to the first source electrode SE1 through a contact hole formed in the planarization layer 120 and the passivation layer 114. Accordingly, the anode AN of the light emitting diode OLED extends to the circuit area to be electrically connected to the first source electrode SE1 of the first transistor TR1 and the second capacitor electrode SC2 of the storage capacitor SC.

In the emission area and the circuit area, the emission layer EL is disposed on the anode AN. The emission layer EL may be formed as one layer over the plurality of sub pixels SP. That is, the emission layers EL of the plurality of sub pixels SP are connected to each other to be integrally formed. The emission layer EL may be configured by one emission layer or may have a structure in which a plurality of emission layers which emits different color light is laminated. The emission layer EL may further include an organic layer, such as a hole injection layer, a hole transport layer, an electron transport layer, and an electron injection layer.

The cathode CA is disposed on the emission layer EL in the emission area and the circuit area. The cathode CA supplies electrons to the emission layer EL so that the cathode may be formed of a conductive material having a low work function. The cathode CA may be formed as one layer over the plurality of sub pixels SP. That is, the cathodes CA of the plurality of sub pixels SP are connected to be integrally formed. For example, the cathode CA may be formed of a transparent conductive material such as indium tin oxide (ITO) and indium zinc oxide (IZO) or ytterbium (Yb) alloy and may further include a metal doping layer, but is not limited thereto.

A bank 120 is disposed on the planarization layer 130 and the anode AN. That is, the bank 130 is disposed on the entire surface of the first substrate 101 in the active area AA and the non-active area NA. The bank 130 may be formed of an insulating material, and for example, formed of polyimide, but is not limited thereto.

Referring to FIGS. 6A to 6C, the bank 130 includes a first bank 130a disposed on the first planarization layer 120a and a second bank 130b disposed on the second planarization layer 120b.

The first bank 130a is disposed to an area of the active area AA and the non-active area NA in which the inorganic layer 110 is disposed, like the first planarization layer 120a. That is, the first bank 130a may be disposed in an area which overlaps the inorganic layer 110. An end of the first bank 130a is located to be the same as the end of the first planarization layer 120a.

In the active area AA, the first bank 130a is disposed between the anode AN and the emission layer EL to cover the edge of the anode AN. The first bank 130a is disposed at the boundary between the sub pixels SP which are adjacent to each other to reduce the color mixture of light emitted from the light emitting diode OLED of each of the plurality of sub pixels SP. In the non-active area NA, the first bank 130a extends from the active area AA to be disposed on the first planarization layer 120a.

The second bank 130b is disposed in an area of the non-active area NA in which the inorganic layer 110 is not disposed. That is, the second bank 130b may be disposed in the non-active area NA which does not overlap the inorganic layer 110. The second bank 130b is not disposed by extending the first bank 130a. That is, the first bank 130a and the second bank 130b may be disposed as separate layers. Therefore, the moisture permeation through the second bank 130b is blocked at the outer peripheral portion of the display device 100 to reduce an initial defect of the light emitting diode OLED.

The second bank 130b may be disposed to have a thickness T4 smaller than a thickness T3 of the first bank 130a. Here, the thickness of the second bank 130b is adjusted by forming a bank material on an entire surface of the first substrate 101 and then etching only an end of the inorganic layer 110, that is, the bank of the outer peripheral portion with respect to the reference line R. Therefore, second height h2 which is the combined thicknesses of the second planarization layer 120b and the second bank 130b may be smaller than first height h1, which is the combined thicknesses of the first planarization layer 120a and the first bank 130a, with respect to the first substrate 101. As described above, in the display device 100 according to the exemplary embodiment of the present disclosure, the first planarization layer 120a and the first bank 130a are formed to have a first height h1 enough to endure the LLO process, in an area in which the inorganic layer 110 is disposed, to suppress the crack of the inorganic layer 110. In an outer peripheral area of the display device 100 in which the inorganic layer 110 is not disposed, the second planarization layer 120b and the second bank 130b are formed to have a second height h2 which is smaller than the first height h1. By doing this, a moisture permeation path through organic layers at the outer peripheral portion of the display device 100 is reduced.

As described above, in the display device 100 according to the exemplary embodiment of the present disclosure, the bank 130 has been described such that the first bank 130a of an area in which the inorganic layer 110 is disposed and the second bank 130b of an area in which the inorganic layer 110 is not disposed are discontinuously formed as separate layers. However, it is not limited thereto.

Referring to FIGS. 7A to 7C, the planarization layer 720 includes a first planarization layer 720a and a second planarization layer 720b.

The first planarization layer 720a is disposed in an area of the active area AA and the non-active area NA in which the inorganic layer 110 is disposed. That is, the first planarization layer 720a may be disposed in an area which overlaps the inorganic layer 110. However, an end of the first planarization layer 720a is located outside more than an end of the inorganic layer 110, and is disposed inside the second substrate 150.

The second planarization layer 720b extends from the first planarization layer 720a and is disposed in a non-active area NA in which the inorganic layer 110 is not disposed. That is, the second planarization layer 720b may be disposed in an area which does not overlap the inorganic layer 110. An end of the second planarization layer 720b coincides with an end of the first substrate 101. The second planarization layer 720b may have a thickness smaller than that of the first planarization layer 720a.

Referring to FIGS. 7A to 7C, the bank 730 includes a second bank 730b formed in an area in which the inorganic layer 110 is not disposed, by extending the first bank 730a in the area in which the inorganic layer 110 is disposed. An end of the first bank 730a according to the second exemplary embodiment may be located outside more than an end of the inorganic layer 110 and an end of the first planarization layer 720a. The first bank 730a and the first planarization layer 720a according to the second exemplary embodiment have first heights h1 or thicknesses and the second bank 730b and the second planarization layer 720b have second heights h2 or thicknesses. The second height h2 is smaller than the first height h1.

When the planarization layer 720 and the bank 730 are formed as described in the second exemplary embodiment, the planarization layer 720 and the bank 730 may be more completely cover the end of the inorganic layer 110. Accordingly, the moisture permeation path through the inorganic layers at the outer peripheral portion is reduced and the crack generated in the inorganic layer 110 is reduced.

The cathode CA is disposed on the bank 130 and the adhesive layer 140 is disposed on the cathode CA.

The second substrate 140 is disposed on the adhesive layer 150. The second substrate 150 serves to protect the light emitting diode OLED from external moisture, oxygen, or impact together with the adhesive layer 140. For example, the second substrate 150 may be formed of a material having a high modulus of approximately 200 to 900 MPa. The second substrate 150 may be formed of a metal material, which has a high corrosion resistance and is easily processed in the form of a foil or a thin film, such as aluminum (Al), nickel (Ni), chromium (Cr), iron (Fe), and an alloy material of nickel. Therefore, as the second substrate 126 is formed of a metal material, the second substrate 126 may be implemented as an ultra-thin film and provide a strong resistance against external impacts and scratches.

The second substrate 150 is not disposed so as to overlap the entire surface of the first substrate 101, but is disposed to the partial area of the non-active area NA. At this time, the second substrate 150 may be disposed to outwardly protrude from the adhesive layer 140.

In the display device 100 according to the exemplary embodiment of the present disclosure, the first substrate 101 is formed of any one of a transparent conducting oxide and an oxide semiconductor to reduce a thickness of the display device 100. In the related art, the plastic substrate has been mainly used as the substrate of the display device. However, the plastic substrate is formed by coating and curing a substrate material at a high temperature so that there are problems in that it takes a long time and it is difficult to form the thickness to be lower than a determined level. In contrast, the transparent conducting oxide and the oxide semiconductor may be formed to have a very thin thickness by the deposition process such as sputtering. Therefore, in the display device 100 according to the exemplary embodiment of the present disclosure, the first substrate 101 is configured by a transparent conducting oxide layer or the oxide semiconductor layer to reduce a thickness of the display device 100 and implement a slim design.

Further, in the display device 100 according to the exemplary embodiment of the present disclosure, the first substrate 101 is formed of a transparent conducting oxide or an oxide semiconductor to improve the flexibility of the display device 100 and reduce the stress generated when the display device 100 is deformed. Specifically, when the first substrate 101 is configured by the transparent conducting oxide layer or the oxide semiconductor, the first substrate 101 may be formed as a very thin film. In this case, the first substrate 101 is also referred to as a first transparent thin film layer. Accordingly, the display device 100 including the first substrate 101 may have a high flexibility and the display device 100 may be easily bent or rolled. Therefore, in the display device 100 according to the exemplary embodiment of the present disclosure, the first substrate 101 is formed by any one of the transparent conducting oxide layer and the oxide semiconductor to improve the flexibility of the display device 100. Accordingly, the stress generated when the display device 100 is deformed is also relieved so that the crack caused in the display device 100 may be reduced.

Further, in the display device 100 according to the exemplary embodiment of the present disclosure, the first substrate 101 is formed of any one of a transparent conducting oxide layer and an oxide semiconductor layer to reduce the possibility of generating the static electricity in the first substrate 101. If the first substrate 101 is formed of plastic so that the static electricity is generated, various wiring lines and driving elements on the first substrate 101 are damaged or the driving is affected due to the static electricity to degrade the display quality. Instead, when the first substrate 101 is formed of the transparent conducting oxide layer or the oxide semiconductor layer, the static electricity generated in the first substrate 101 is reduced and a configuration for blocking and discharging the static electricity may be simplified. Accordingly, in the display device 100 according to the exemplary embodiment of the present disclosure, the first substrate 101 is formed of any one of the transparent conducting oxide layer or the oxide semiconductor having a low possibility of generating the static electricity. By doing this, the damage or the display quality degradation due to the static electricity may be reduced.

Further, in the display device 100 according to the exemplary embodiment of the present disclosure, the first substrate 101 is formed of one of the transparent conducting oxide and the oxide semiconductor to reduce the permeation of the moisture or oxygen of the outside into the display device 100 by means of the first substrate 101. When the first substrate 101 is formed of the transparent conducting oxide layer or the oxide semiconductor, the first substrate 101 is formed in a vacuum environment so that the foreign material generation possibility is significantly low. Further, even though the foreign material is generated, the size of the foreign material is very small so that the permeation of the moisture and oxygen into the display device 100 may be reduced. Accordingly, in the display device 100 according to the exemplary embodiment of the present disclosure, the first substrate 101 is formed of a transparent conducting oxide or the oxide semiconductor having a low possibility of generating the foreign materials and an excellent moisture permeation performance. By doing this, the reliability of the light emitting diode OLED including an organic layer and the display device 100 may be improved.

In the display device 100 according to the exemplary embodiment of the present disclosure, the first substrate 101 is formed of any one of a transparent conducting oxide and an oxide semiconductor to attach a barrier film which is thin and cheap below the first substrate 101. When the first substrate 101 is formed of a material having a low moisture permeation performance, for example, plastic, the moisture permeation performance may be supplemented by attaching a high performance barrier film. However, in the display device 100 according to the exemplary embodiment of the present disclosure, the first substrate 101 is formed of a transparent conducting oxide or an oxide semiconductor having an excellent moisture permeation performance so that a thin and cheap barrier film may be attached below the first substrate 101. Accordingly, in the display device 100 according to the exemplary embodiment of the present disclosure, the first substrate 101 is configured by any one of the transparent conducting oxide or the oxide semiconductor having an excellent moisture permeation performance to reduce the manufacturing cost of the display device.

Further, in the display device 100 according to the exemplary embodiment of the present disclosure, the first substrate 101 is formed of any one of a transparent conducting oxide and an oxide semiconductor to perform a laser lift off (LLO) process. When the display device 100 is manufactured, a temporary substrate in which a sacrificial layer is formed is attached below the first substrate 101 and then a pixel unit PD is formed on the first substrate 101. The sacrificial layer may use a hydrogenated amorphous silicon or an amorphous silicon which is hydrogenated and doped with impurities. After completing the manufacturing of the display device 100, when a laser is irradiated from the lower portion of the temporary substrate, the hydrogen of the sacrificial layer is dehydrogenated and the sacrificial layer and the temporary substrate may be separated from the first substrate 101. At this time, the transparent conducting oxide and the oxide semiconductor are materials which may perform the LLO process with the sacrificial layer and the temporary substrate. Therefore, even though the first substrate 101 is formed of any one of the transparent conducting oxide or the oxide semiconductor, the first substrate 101 may be easily separated from the temporary substrate. Accordingly, in the display device 100 according to the exemplary embodiment of the present disclosure, the first substrate 101 is configured by one of the transparent conducting oxide layer or the oxide semiconductor which may perform the LLO process. Therefore, the display device 100 may be easily manufactured with the existing process and equipment.

Further, in the display device 100 according to the exemplary embodiment of the present disclosure, without reducing the heights or thicknesses of the first planarization layer 120a, 720a and the first bank 130a, 730a disposed in a partial area of the active area AA and the non-active area NA in which the inorganic layer 110 is disposed, but the second planarization layer 120b, 720b and the second bank 130b, 730b disposed in the outer peripheral area of the non-active area NA in which the inorganic layer 110 is not disposed have heights or thicknesses smaller than those of the first planarization layer 120a, 720a and the first bank 130a, 730a.

Regardless of the placement of the inorganic layer, when the planarization layer and the bank are formed to have the same level of top surface to the outer peripheral portion of the active area AA and the non-active area NA, the non-active area in which the inorganic layer is not disposed should have a thickness larger than that of the active area and the non-active area in which the inorganic layer is disposed with respect to the first substrate. Therefore, thick organic layers are formed in the outer peripheral portion of the display device and the inorganic layer is cracked due to the moisture permeation by the thick organic layers. Specifically, the flexible film is disposed in an area of the outer peripheral portion of the display device in which the flexible film is disposed so that the moisture permeation is difficult. In contrast, in the outer peripheral area of the display device in which the flexible film is not disposed, the moisture permeation is easy so that the inorganic layer is cracked.

Accordingly, in the display device 100 according to the exemplary embodiment of the present disclosure, the heights of the second planarization layers 120b and 720b and the second banks 130b and 730b disposed on the non-active area NA in which the inorganic layer 110 is not disposed are smaller than heights of the first planarization layers 120a and 720a and the first banks 130a and 730a disposed on the active area AA and the non-active area NA in which the inorganic layer 110 is disposed. Therefore, the moisture permeation path by the organic layer is reduced to reduce the crack generated in the inorganic layer 110.

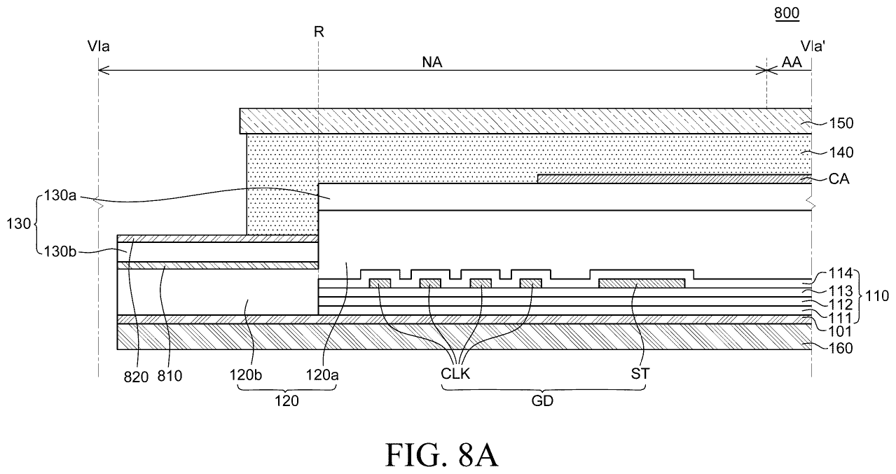

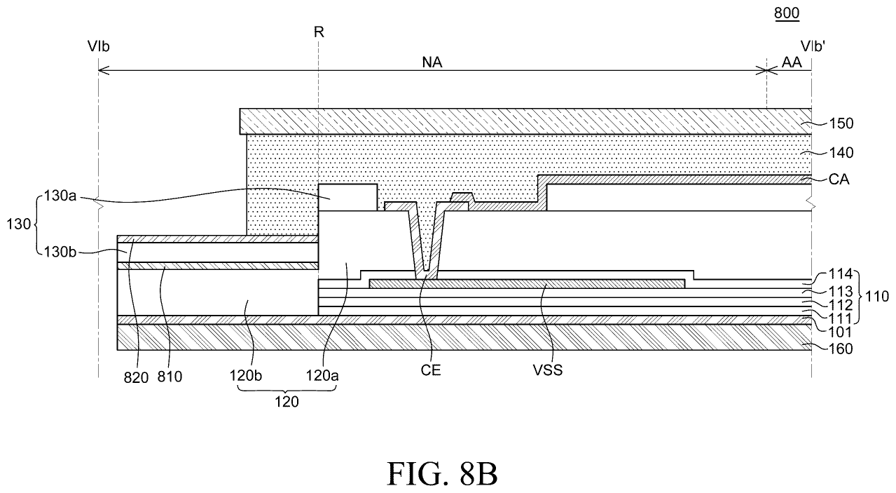

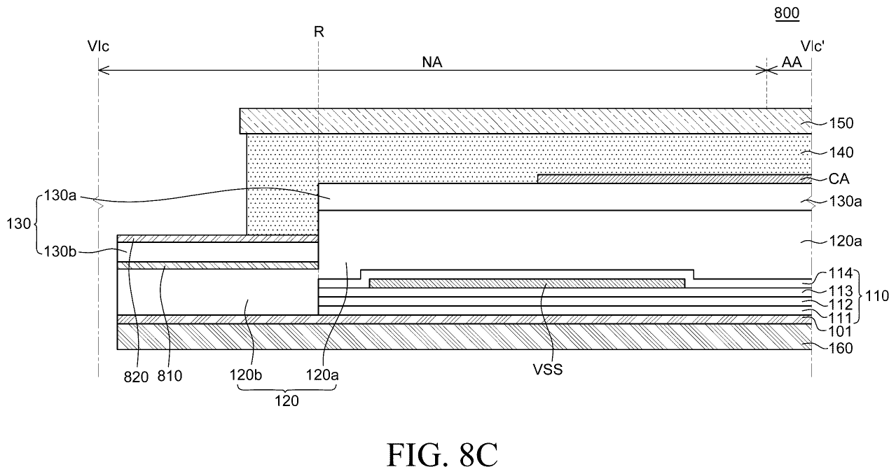

FIG. 8A is a cross-sectional view of a third exemplary embodiment taken along the line VIa-VIa′ of FIG. 1. FIG. 8B is a cross-sectional view of a third exemplary embodiment taken along VIb-VIb′ of FIG. 1. FIG. 8C is a cross-sectional view of a third exemplary embodiment taken along VIc-VIc′ of FIG. 1. The only difference between a display device 800 of FIGS. 8A to 8C and the display device 100 of FIGS. 1 to 6C is a first moisture permeation suppression layer 810 and a second moisture permeation suppression layer 820, but other configurations are substantially the same, so that a redundant description will be omitted.

Referring to FIGS. 8A to 8C, in the area in which the inorganic layer 110 is not disposed 110, that is, the non-active NA which does not overlap the inorganic layer 110, the first moisture permeation suppression layer 810 and the second moisture permeation suppression layer 820 are disposed.

The first moisture permeation suppression layer 810 is disposed on the second planarization layer 120b. The first moisture permeation suppression layer 810 may be formed of an inorganic material, for example, may be configured by a single layer or a double layer of silicon oxide (SiOx) or silicon nitride (SiNx), but is not limited thereto.

The second moisture permeation suppression layer 820 is disposed on the entire second bank 130b. The second moisture permeation suppression layer 820 may be formed of an inorganic material, for example, may be configured by a single layer or a double layer of silicon oxide (SiOx) or silicon nitride (SiNx), but is not limited thereto.

As described above, in the display device 800 according to another exemplary embodiment of the present disclosure, the first moisture permeation suppression layer 810 and the second moisture permeation suppression layer 820 which are formed of an inorganic material suitables for the moisture permeation are disposed above the second planarization layer 120b and the second bank 130b disposed in the non-active area NA which does not overlap the inorganic layer 110. A moisture permeation speed through an interface between the organic layer and the inorganic layer is slower than a moisture permeation speed through an interface between two organic layers. Accordingly, in the display device 800 according to another exemplary embodiment of the present disclosure, the first moisture permeation suppression layer 810 and the second moisture permeation suppression layer 820 are disposed at the outer peripheral portion to more slowly permeate the moisture through the outer peripheral portion.

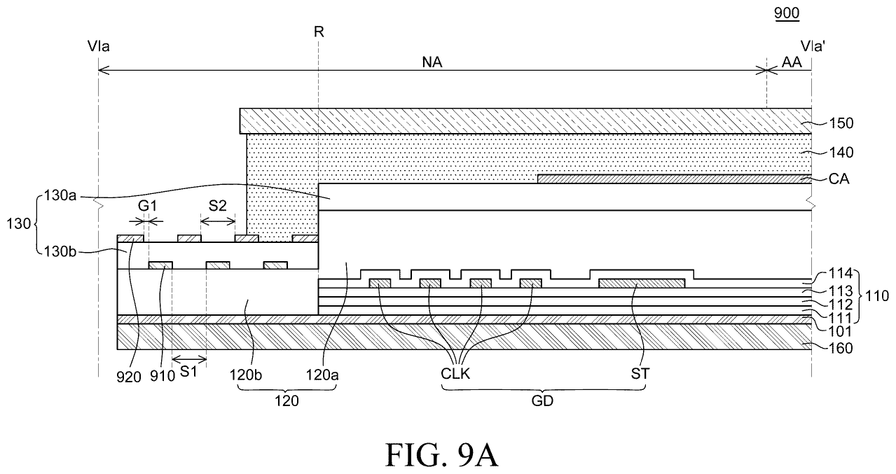

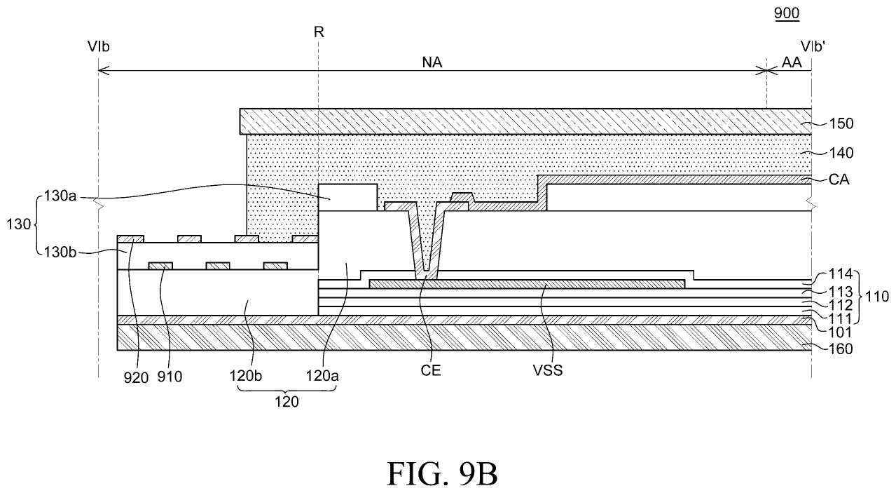

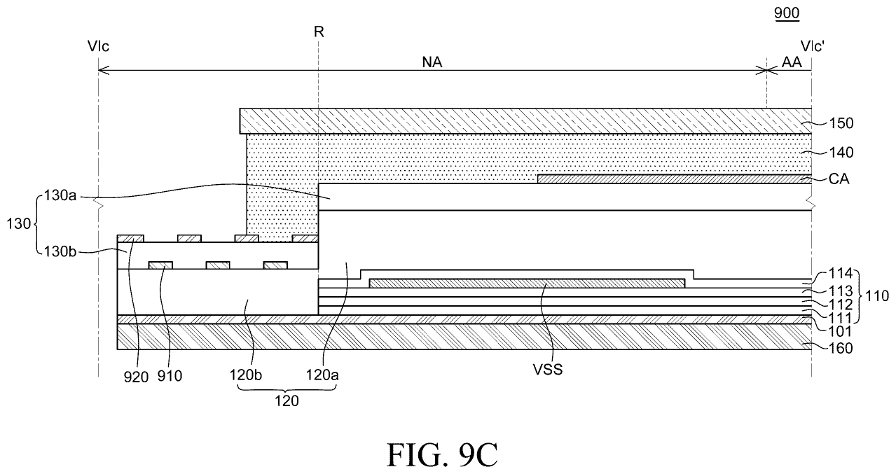

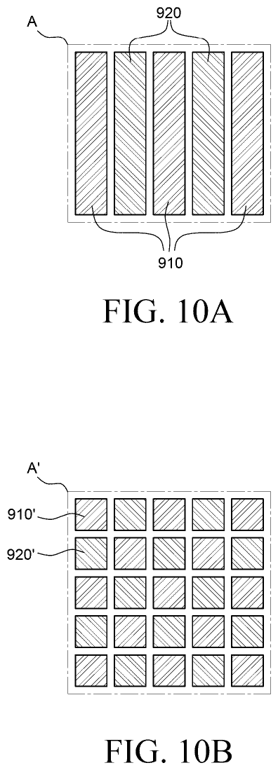

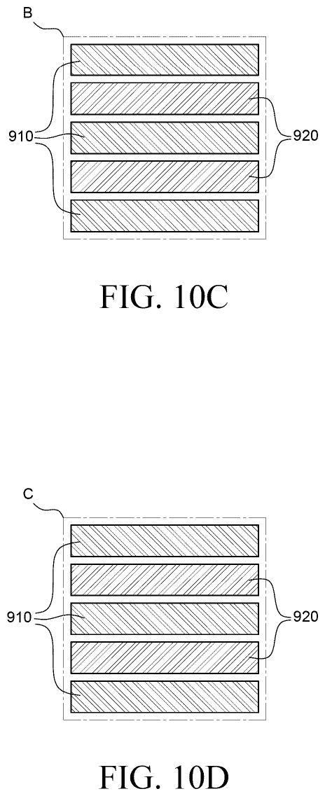

FIG. 9A is a cross-sectional view of a fourth exemplary embodiment taken along the line VIa-VIa′ of FIG. 1. FIG. 9B is a cross-sectional view of a fourth exemplary embodiment taken along VIb-VIb′ of FIG. 1. FIG. 9C is a cross-sectional view of a fourth exemplary embodiment taken along VIc-VIc′ of FIG. 1. FIGS. 10A and 10B are schematic enlarged plan views of a fourth exemplary embodiment of an area A of FIG. 1. FIG. 10C is a schematic enlarged plan view of an area B of FIG. 1 according to a fourth exemplary embodiment. FIG. 10D is a schematic enlarged plan view of an area C of FIG. 1 according to a fourth exemplary embodiment. The only difference between a display device 900 of FIGS. 9A to 10D and the display device 100 of FIGS. 1 to 6C is a first moisture permeation suppression pattern 910 and a second moisture permeation suppression pattern 920, but other configurations are substantially the same, so that a redundant description will be omitted.

Referring to FIGS. 9A to 9C, in the area in which the inorganic layer 110 is not disposed 110, that is, the non-active NA which does not overlap the inorganic layer 110, a plurality of first moisture permeation suppression patterns 910 and a plurality of second moisture permeation suppression patterns 920 are disposed.

The plurality of first moisture permeation suppression patterns 910 is disposed on the second planarization layer 120b. The plurality of first moisture permeation suppression patterns 910 is disposed to be spaced apart from each other with a determined interval, e.g., a predetermined interval. At this time, the determined interval may be larger than a width of the first moisture permeation pattern 910. The plurality of first moisture permeation suppression patterns 910 may be formed of an inorganic material, and for example, may be configured by a single layer or a double layer of silicon oxide (SiOx) or silicon nitride (SiNx), but is not limited thereto.

The plurality of second moisture permeation suppression patterns 920 is disposed on the second bank 130b. Each of the plurality of second moisture permeation suppression patterns 920 is formed to have the same width as the width of each of the plurality of first moisture permeation suppression patterns 910. The plurality of second moisture permeation suppression patterns 920 is disposed to be spaced apart from each other with a determined interval. At this time, the determined interval may be larger than a width of the second moisture permeation pattern 920. The plurality of second moisture permeation suppression patterns 920 may be formed of an inorganic material, for example, may be configured by a single layer or a double layer of silicon oxide (SiOx) or silicon nitride (SiNx), but is not limited thereto.

The plurality of first moisture permeation suppression patterns 910 and the plurality of second moisture permeation suppression patterns 920 are disposed so as not to overlap each other. That is, the plurality of second moisture permeation suppression patterns 920 disposed on the second bank 130b may be disposed so as to overlap a space S1 between the plurality of first moisture permeation suppression patterns 910 disposed on the second planarization layer 120b. The plurality of first moisture permeation suppression patterns 910 may be disposed so as to overlap a space S2 between the plurality of second moisture permeation suppression patterns 920. For example, referring to FIGS. 9A to 9C, the plurality of first moisture permeation suppression patterns 910 and the plurality of second moisture permeation suppression patterns 920 are disposed to have a zigzag shape in a cross-sectional view. Further, each moisture permeation suppression pattern is spaced apart from an adjacent moisture permeation suppression pattern with a distance larger than a width thereof. For example, a projection of a first moisture permeation suppression patterns 910 on second bank 130b may have a gap G1 from the adjacent second moisture permeation suppression patterns 920. Accordingly, the plurality of first moisture permeation suppression patterns 910 and the plurality of second moisture permeation suppression patterns 920 do not completely overlap. The placement shape of the plurality of first moisture permeation suppression patterns 910 and the plurality of second moisture permeation suppression patterns 920 will be described in plan view.

Referring to FIG. 10A, in the non-active area NA (A in FIG. 1) in which the gate driver GD is disposed, the plurality of first moisture permeation suppression patterns 910 and the plurality of second moisture permeation suppression patterns 920 are alternately disposed in the same column direction as a direction in which the data line DL is disposed in the active area AA. That is, the plurality of first moisture permeation suppression patterns 910 and the plurality of second moisture permeation suppression patterns 920 are alternately disposed in the column direction.

The plurality of first moisture permeation suppression patterns 910 and the plurality of second moisture permeation suppression patterns 920 which are alternately disposed may be spaced apart from each other with a determined interval. As described above, the plurality of first moisture permeation suppression patterns 910 is disposed on the second planarization layer 120b with a distance larger than a width of the first moisture permeation suppression pattern 910. Further, the plurality of second moisture permeation suppression patterns 920 is disposed on the second bank 130b with a distance larger than a width of the second moisture permeation suppression pattern 920. Therefore, the first moisture permeation suppression pattern 910 and the second moisture permeation suppression pattern 920 which are adjacent to each other are also disposed to be spaced apart from each other.

As described above, in the non-active area NA in which the gate driver GD is disposed, the plurality of first moisture permeation suppression patterns 910 and the plurality of second moisture permeation suppression patterns 920 are alternately disposed in the column direction same as a direction in which the data line DL is disposed. However, it is not limited thereto.

Referring to FIG. 10B, in the non-active area NA in which the gate driver GD is disposed, a plurality of first moisture permeation suppression patterns 910′ and a plurality of second moisture permeation suppression patterns 920′ are alternately disposed in the row direction in which the gate line GL is disposed and in the column direction in which the data line DL is disposed in the active area AA. Therefore, the plurality of first moisture permeation suppression patterns 910′ and the plurality of second moisture permeation suppression patterns 920′ are disposed in matrix. In other words, referring to FIG. 10B, the plurality of first moisture permeation suppression patterns 910′ and the plurality of second moisture permeation suppression patterns 920′ have island shapes.

Next, in the display device 900, a plurality of first moisture permeation suppression patterns 910 and a plurality of second moisture permeation suppression patterns 920 in an area B which is not connected to the flexible film 170 at a side in which the flexible film 170 is disposed and in an area C of the display device 900 at an opposite side of the area which is connected to the flexible film 170 will be described.

Referring to FIGS. 10C and 10D, in the non-active area NA (B in FIG. 1) which is not connected to the flexible film 170 and in the non-active area NA (C in FIG. 1) which is opposite to the area in which the flexible film 170 is disposed, the plurality of first moisture permeation suppression patterns 910 and the plurality of second moisture permeation suppression patterns 920 are alternately disposed in the same direction as a direction in which the gate line GL is disposed in the active area AA. That is, the plurality of first moisture permeation suppression patterns 910 and the plurality of second moisture permeation suppression patterns 920 are alternately disposed in the column direction.

The plurality of first moisture permeation suppression patterns 910 and the plurality of second moisture permeation suppression patterns 920 which are alternately disposed may be spaced apart from each other with a determined interval. As described above, the plurality of first moisture permeation suppression patterns 910 is disposed on the second planarization layer 120b with a distance larger than a width of the first moisture permeation suppression pattern 910. Further, the plurality of second moisture permeation suppression patterns 920 is disposed on the second bank 130b with a distance larger than a width of the second moisture permeation suppression pattern 920. Therefore, the first moisture permeation suppression pattern 910 and the second moisture permeation suppression pattern 920 which are adjacent to each other are also disposed to be spaced apart from each other.

As described above, in the display device 900 according to another exemplary embodiment of the present disclosure, an inorganic material which is suitable for the moisture permeation is disposed above the second planarization layer 120b and the second bank 130b disposed in the non-active area NA which does not overlap the inorganic layer 110. In this case, the plurality of first moisture permeation suppression patterns 910 and the plurality of second moisture permeation suppression patterns 920 are disposed so that the inorganic layer has a plurality of pattern shapes. A moisture permeation speed through an interface between the organic layer and the inorganic layer is slower than a moisture permeation speed through an interface between two organic layers. Accordingly, in the display device 900 according to another exemplary embodiment of the present disclosure, the plurality of first moisture permeation suppression patterns 910 and the plurality of second moisture permeation suppression patterns 920 are disposed at the outer peripheral portion to more slowly permeate the moisture through the outer peripheral portion. Specifically, the plurality of first moisture permeation suppression patterns 910 and the plurality of second moisture permeation suppression patterns 920 have a pattern shape so that the moisture permeation path is increased due to the step, which may delay the moisture permeation.

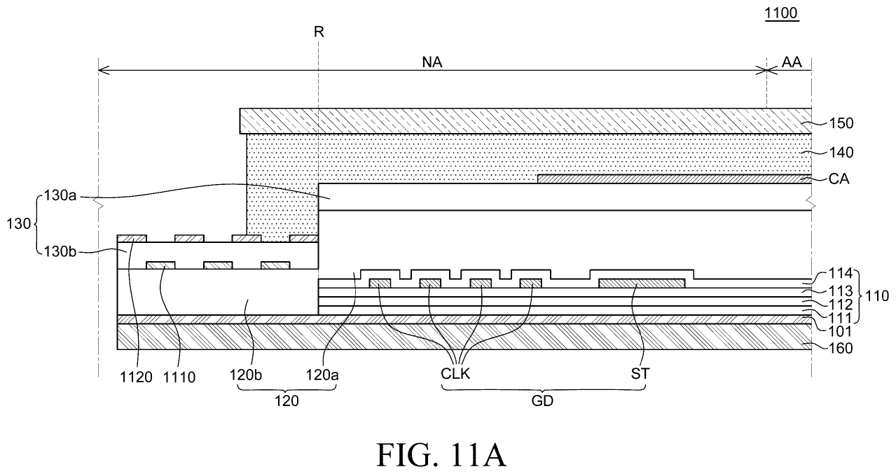

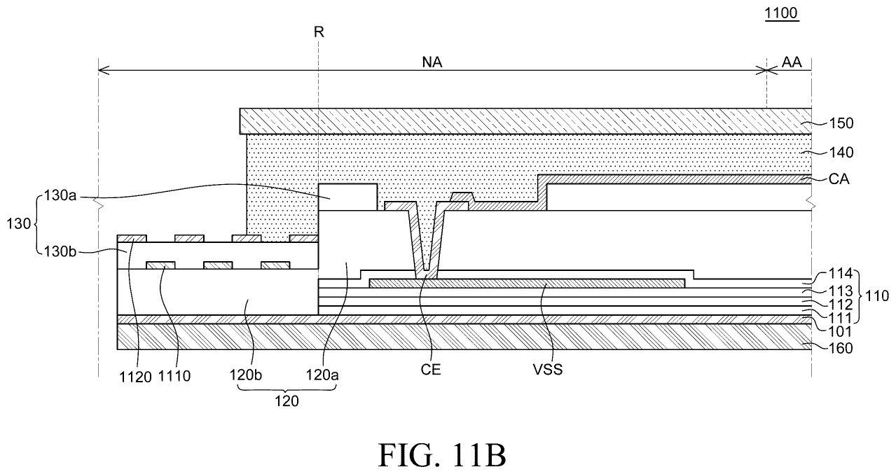

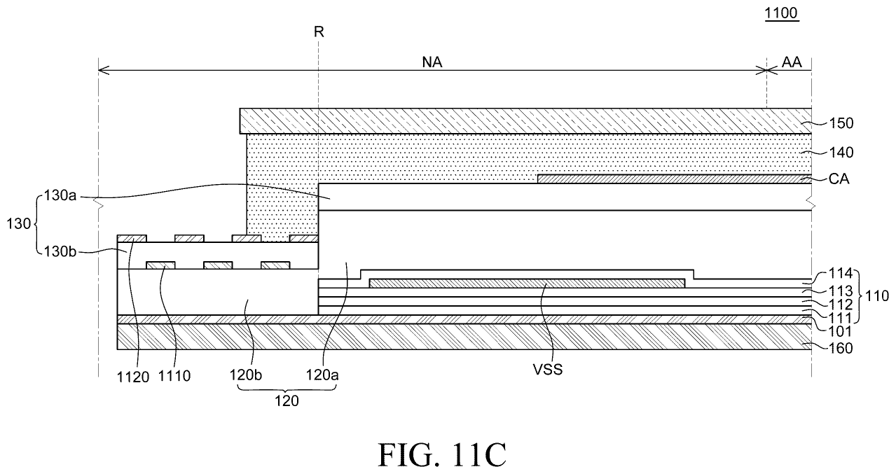

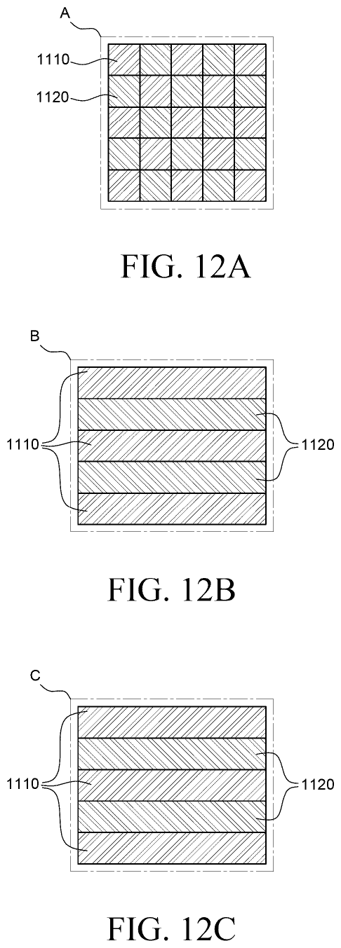

FIG. 11A is a cross-sectional view of a fifth exemplary embodiment taken along the line VIa-VIa′ of FIG. 1. FIG. 11B is a cross-sectional view of a fifth exemplary embodiment taken along VIb-VIb′ of FIG. 1. FIG. 11C is a cross-sectional view of a fifth exemplary embodiment taken along VIc-VIc′ of FIG. 1. FIG. 12A is a schematic enlarged plan view of an area A of FIG. 1 according to a fifth exemplary embodiment. FIG. 12B is a schematic enlarged plan view of an area B of FIG. 1 according to a fifth exemplary embodiment. FIG. 12C is a schematic enlarged plan view of an area C of FIG. 1 according to a fifth exemplary embodiment. The only difference between a display device 1100 of FIGS. 11A to 12C and the display device 100 of FIGS. 1 to 6C is a first moisture permeation suppression pattern 1110 and a second moisture permeation suppression pattern 1120, but other configurations are substantially the same, so that a redundant description will be omitted.

Referring to FIGS. 11A to 11C, in the area in which the inorganic layer 110 is not disposed 110, that is, the non-active NA which does not overlap the inorganic layer 110, a plurality of first moisture permeation suppression patterns 1110 and a plurality of second moisture permeation suppression patterns 1120 are disposed.

The plurality of first moisture permeation suppression patterns 1110 is disposed on the second planarization layer 120b. The plurality of first moisture permeation suppression patterns 1110 is disposed to be spaced apart from each other with a determined interval. At this time, the determined interval may be equal to a width of the first moisture permeation pattern 1110. The plurality of first moisture permeation suppression patterns 1110 may be formed of an inorganic material, for example, may be configured by a single layer or a double layer of silicon oxide (SiOx) or silicon nitride (SiNx), but is not limited thereto.

The plurality of second moisture permeation suppression patterns 1120 is disposed on the second bank 130b. Each of the plurality of second moisture permeation suppression patterns 1120 is formed to have the same width as the width of each of the plurality of first moisture permeation suppression patterns 1110. The plurality of second moisture permeation suppression patterns 1120 is spaced apart from each other as much as the width of each of the plurality of second moisture permeation suppression patterns 1120. The plurality of second moisture permeation suppression patterns 1120 may be formed of an inorganic material, for example, may be configured by a single layer or a double layer of silicon oxide (SiOx) or silicon nitride (SiNx), but is not limited thereto.

The plurality of first moisture permeation suppression patterns 1110 and the plurality of second moisture permeation suppression patterns 1120 are disposed so as not to overlap each other. That is, the plurality of second moisture permeation suppression patterns 1120 disposed on the second bank 130b may be disposed so as to overlap a space between the plurality of first moisture permeation suppression patterns 1110 disposed on the second planarization layer 120b. For example, referring to FIGS. 11A to 11C, the plurality of first moisture permeation suppression patterns 1110 and the plurality of second moisture permeation suppression patterns 1120 are disposed to have a zigzag shape in a cross-sectional view. However, the plurality of first moisture permeation suppression patterns 1110 and the plurality of second moisture permeation suppression patterns 1120 are spaced apart from each other as much as a width of the pattern. Therefore, in plan view, there is no space between the first moisture permeation suppression pattern 1110 and the second moisture permeation suppression pattern 1120. The placement shape of the plurality of first moisture permeation suppression patterns 1110 and the plurality of second moisture permeation suppression patterns 1120 will be described in plan view.

Referring to FIG. 12A, in the non-active area NA (A in FIG. 1) in which the gate driver GD is disposed, the plurality of first moisture permeation suppression patterns 1110 and the plurality of second moisture permeation suppression patterns 1120 are alternately disposed in a direction in which the gate line GL is disposed and in a direction in which the data line DL is disposed in the active area AA. Therefore, the plurality of first moisture permeation suppression patterns 1110 and the plurality of second moisture permeation suppression patterns 1120 are disposed in matrix. In other words, the plurality of first moisture permeation suppression patterns 1110 and the plurality of second moisture permeation suppression patterns 1120 have island shapes.

A first moisture permeation suppression pattern 1110 and a second moisture permeation suppression pattern 1120 which are adjacent in plan view are not spaced apart from each other. That is, a boundary of the first moisture permeation suppression pattern 1110 disposed on the second planarization layer 120b and a boundary of the second moisture permeation suppression pattern 1120 disposed on the second bank 130b may match. Therefore, the adjacent second moisture permeation suppression patterns 1120 which are disposed on the second bank 130b are spaced apart from each other as much as a width thereof so that the moisture permeates through the space, the first permeation suppression pattern 1110 is disposed on the second planarization layer 120b which overlaps the space through which the moisture permeates. Therefore, the moisture permeation through the outer peripheral portion may be reduced.

Next, in the display device 1100, a plurality of first moisture permeation suppression patterns 1110 and a plurality of second moisture permeation suppression patterns 1120 in an area B which is not connected to the flexible film 170 at a side in which the flexible film 170 is disposed and in an area C of the display device 1100 at an opposite side of the area which is connected to the flexible film 170 will be described.

Referring to FIGS. 12B and 12C, in the non-active area NA (B in FIG. 1) which is not connected to the flexible film 170 and in the non-active area NA (C in FIG. 1) which is opposite to the area in which the flexible film 170 is disposed, the plurality of first moisture permeation suppression patterns 1110 and the plurality of second moisture permeation suppression patterns 1120 are alternately disposed in the same direction as a direction in which the gate line GL is disposed in the active area AA. That is, the plurality of first moisture permeation suppression patterns 1110 and the plurality of second moisture permeation suppression patterns 1120 are alternately disposed.

The plurality of first moisture permeation suppression patterns 1110 and the plurality of second moisture permeation suppression patterns 1120 which are alternately disposed are not spaced apart from each other in plan view. That is, the plurality of first moisture permeation suppression patterns 1110 is disposed on the second planarization layer 120b as much as a width of the first moisture permeation suppression pattern 1110. Further, the plurality of second moisture permeation suppression patterns 1120 is disposed on the second bank 130b as much as a width of the second moisture permeation suppression pattern 1120. Therefore, the first moisture permeation suppression pattern 1110 and the second moisture permeation suppression pattern 1120 which are adjacent to each other in plan view are also not disposed to be spaced apart from each other.

As described above, in the display device 1100 according to another exemplary embodiment of the present disclosure, the plurality of first moisture permeation suppression patterns 1110 and the plurality of second moisture permeation suppression patterns 1120 which are more suitable for moisture permeation are disposed above the second planarization layer 120b and the second bank 130b disposed in the non-active area NA which does not overlap the inorganic layer 110. However, the plurality of second moisture permeation suppression patterns 1120 is disposed so as to overlap a space between the plurality of first moisture permeation suppression patterns 1110 without the space from the first moisture permeation suppression pattern 1110. A moisture permeation speed through an interface between the organic layer and the inorganic layer is slower than a moisture permeation speed through an interface between two organic layers. Accordingly, in the display device 1100 according to another exemplary embodiment of the present disclosure, the plurality of first moisture permeation suppression patterns 1110 and the plurality of second moisture permeation suppression patterns 1120 are disposed at the outer peripheral portion to more slowly permeate the moisture through the outer peripheral portion. Specifically, the plurality of first moisture permeation suppression patterns 1110 and the plurality of second moisture permeation suppression patterns 1120 are alternately disposed without having a space therebetween in plan view so that the moisture permeation path is increased, which may delay the moisture permeation.

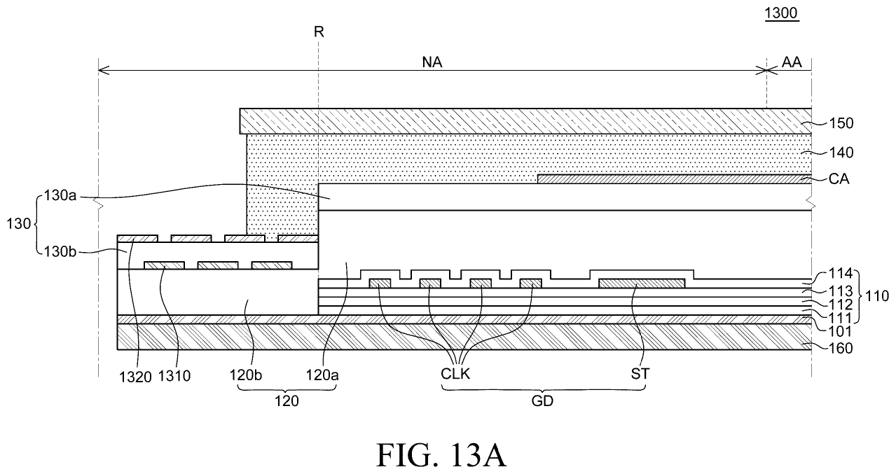

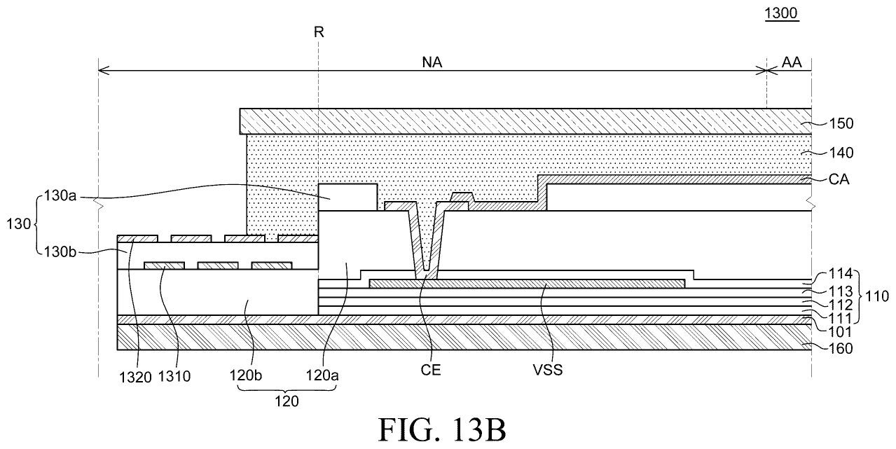

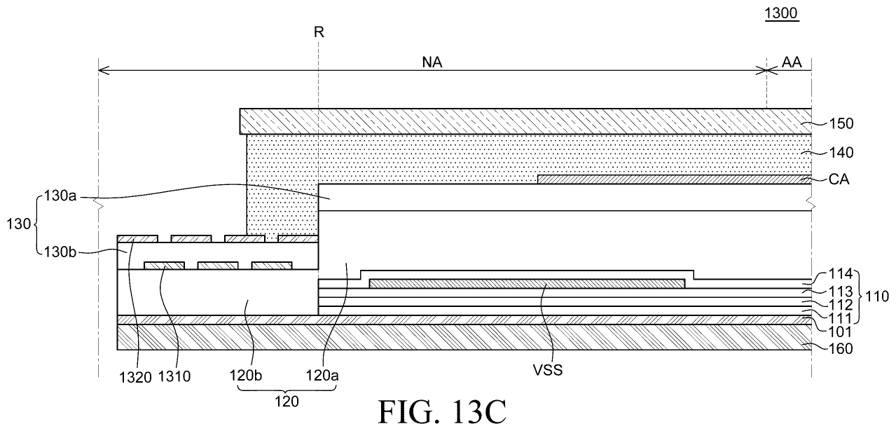

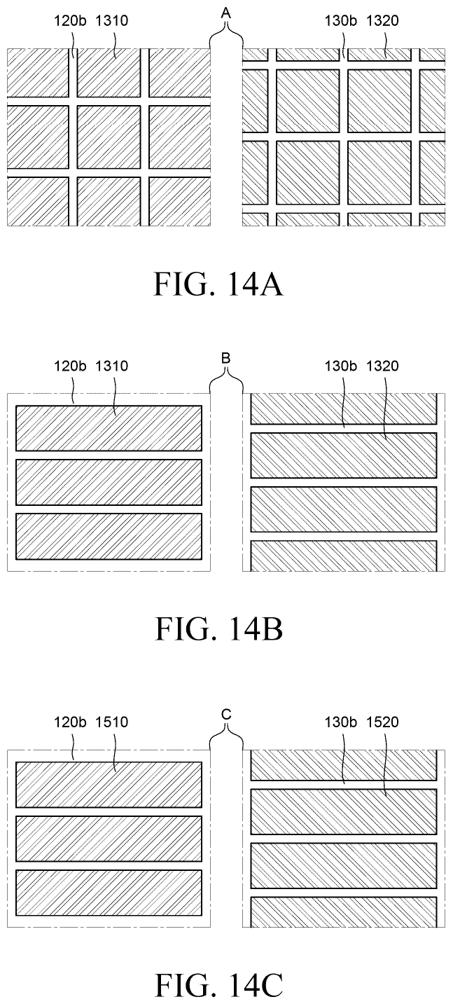

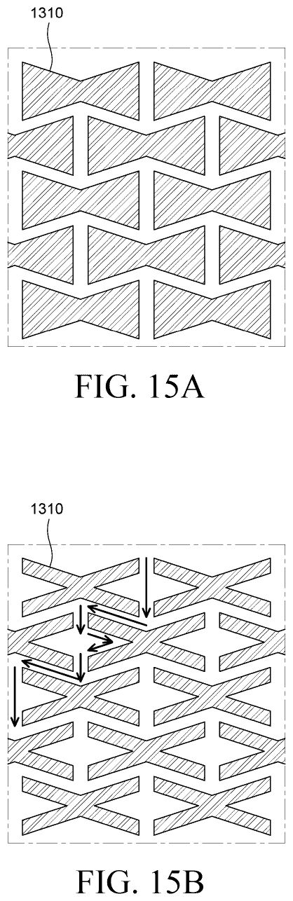

FIG. 13A is a cross-sectional view of a sixth exemplary embodiment taken along the line VIa-VIa′ of FIG. 1. FIG. 13B is a cross-sectional view of a sixth exemplary embodiment taken along VIb-VIb′ of FIG. 1. FIG. 13C is a cross-sectional view of a sixth exemplary embodiment taken along VIc-VIc′ of FIG. 1. FIG. 14A is a schematic enlarged plan view of an area A of FIG. 1 according to a sixth exemplary embodiment. FIG. 14B is a schematic enlarged plan view of an area B of FIG. 1 according to a sixth exemplary embodiment. FIG. 14C is a schematic enlarged plan view of an area C of FIG. 1 according to a sixth exemplary embodiment. FIGS. 15A and 15B are schematic enlarged plan views illustrating an example of another shape of a permeation suppression pattern according to a sixth exemplary embodiment. The only difference between a display device 1300 of FIGS. 13A to 14C and the display device 100 of FIGS. 1 to 6C is a first moisture permeation suppression pattern 1310 and a second moisture permeation suppression pattern 1320, but other configurations are substantially the same, so that a redundant description will be omitted.

Referring to FIGS. 13A to 13C, in the area in which the inorganic layer 110 is not disposed, that is, the non-active NA which does not overlap the inorganic layer 110, a plurality of first moisture permeation suppression patterns 1310 and a plurality of second moisture permeation suppression patterns 1320 are disposed.

The plurality of first moisture permeation suppression patterns 1310 is disposed on the second planarization layer 120b. The plurality of first moisture permeation suppression patterns 1310 is disposed to be spaced apart from each other with a determined interval. At this time, the determined interval may be smaller than a width of the first moisture permeation pattern 1310. The plurality of first moisture permeation suppression patterns 1310 may be formed of an inorganic material, for example, may be configured by a single layer or a double layer of silicon oxide (SiOx) or silicon nitride (SiNx), but is not limited thereto.

The plurality of second moisture permeation suppression patterns 1320 is disposed on the second bank 130b. Each of the plurality of second moisture permeation suppression patterns 1320 is formed to have the same width as the width of each of the plurality of first moisture permeation suppression patterns 1310. The plurality of second moisture permeation suppression patterns 1320 is spaced apart from each other with a distance smaller than the width of each of the plurality of second moisture permeation suppression patterns 1320. Therefore, the plurality of first moisture permeation suppression patterns 1310 and the plurality of second moisture permeation suppression patterns 1320 partially overlap. The plurality of second moisture permeation suppression patterns 1120 may be formed of an inorganic material, for example, may be configured by a single layer or a double layer of silicon oxide (SiOx) or silicon nitride (SiNx), but is not limited thereto. The placement shape of the plurality of first moisture permeation suppression patterns 1310 and the plurality of second moisture permeation suppression patterns 1320 will be described in plan view.

Referring to FIG. 14A, in the non-active area NA (A in FIG. 1) in which the gate driver GD is disposed, the plurality of first moisture permeation suppression patterns 1310 and the plurality of second moisture permeation suppression patterns 1320 are alternately disposed in a direction in which the gate line GL is disposed and in a direction in which the data line DL is disposed in the active area AA. In this case, the plurality of first moisture permeation suppression patterns 1310 and the plurality of second moisture permeation suppression patterns 1320 partially overlap. The plurality of first moisture permeation suppression patterns 1310 and the plurality of second moisture permeation suppression patterns 1320 have island shapes.

Next, in the display device 1300, a plurality of first moisture permeation suppression patterns 1310 and a plurality of second moisture permeation suppression patterns 1320 in an area B which is not connected to the flexible film 170 at a side in which the flexible film 170 is disposed and in an area C of the display device 1300 at an opposite side of the area which is connected to the flexible film 170 will be described.

Referring to FIGS. 14B and 14C, in the non-active area NA (B in FIG. 1) which is not connected to the flexible film 170 and in the non-active area NA (C in FIG. 1) which is opposite to the area in which the flexible film 170 is disposed, the plurality of first moisture permeation suppression patterns 1310 and the plurality of second moisture permeation suppression patterns 1320 are alternately disposed in the same direction as a direction in which the gate line GL is disposed in the active area AA. That is, the plurality of first moisture permeation suppression patterns 1310 and the plurality of second moisture permeation suppression patterns 1320 are alternately disposed.

The plurality of first moisture permeation suppression patterns 1310 and the plurality of second moisture permeation suppression patterns 1320 which are alternately disposed may partially overlap. As described above, this is because the plurality of first moisture permeation suppression patterns 1310 is disposed on the second planarization layer 120b to be spaced apart from each other with a distance smaller than a width of the first moisture permeation suppression pattern 1310. Further, the plurality of second moisture permeation suppression patterns 1320 is disposed on the second bank 130b to be spaced apart from each other with a distance smaller than a width of the second moisture permeation suppression pattern 1320.

As described above, in the display device 1300 according to another exemplary embodiment of the present disclosure, the plurality of first moisture permeation suppression patterns 1310 and the plurality of second moisture permeation suppression patterns 1320 which are more suitable for moisture permeation are disposed above the second planarization layer 120b and the second bank 130b disposed in the non-active area NA which does not overlap the inorganic layer 110. However, the plurality of first moisture permeation suppression patterns 1310 and the plurality of second moisture permeation suppression patterns 1320 are disposed so as to partially overlap. A moisture permeation speed through an interface between the organic layer and the inorganic layer is slower than a moisture permeation speed through an interface between two organic layers. Accordingly, in the display device 1300 according to another exemplary embodiment of the present disclosure, the plurality of first moisture permeation suppression patterns 1310 and the plurality of second moisture permeation suppression patterns 1320 are disposed at the outer peripheral portion to more slowly permeate the moisture through the outer peripheral portion. Specifically, the plurality of first moisture permeation suppression patterns 1310 and the plurality of second moisture permeation suppression patterns 1320 are alternately disposed so as to partially overlap in plan view so that the moisture permeation path is increased, which may delay the moisture permeation.

The plurality of first moisture permeation suppression patterns 1310 and the plurality of second moisture permeation suppression patterns 1320 may be formed to have different shapes in plan view. This will be described in more detail with reference to FIGS. 15A and 15B together.

As illustrated in FIG. 15A, the plurality of first moisture permeation suppression patterns 1310 may have a butterfly-shaped pattern to increase the moisture permeation path or as illustrated in FIG. 15B, may have an X-shaped pattern. Even though it is not illustrated in the drawing, the plurality of second moisture permeation suppression patterns 1320 is also have the same shape as the shape of the plurality of first moisture permeation suppression patterns 1310 illustrated in FIGS. 15A and 15B and partially overlaps the plurality of first moisture permeation suppression patterns 1310. As described above, the plurality of first moisture permeation suppression patterns 1310 and the plurality of second moisture permeation suppression patterns 1320 are formed to have various shapes to increase the moisture permeation path of the outer peripheral portion to reduce the defect of the light emitting diode due to the moisture permeation.

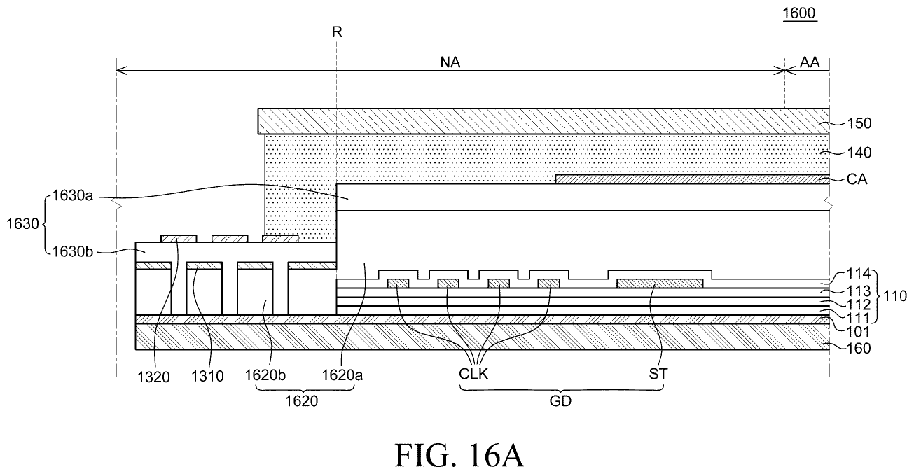

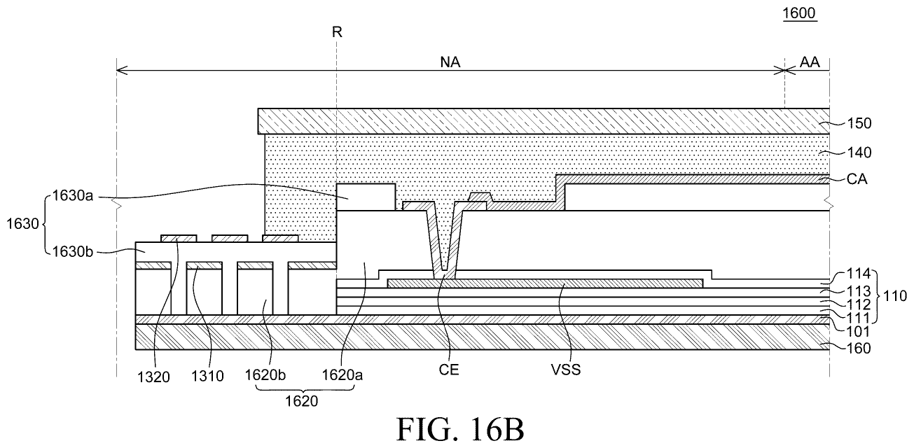

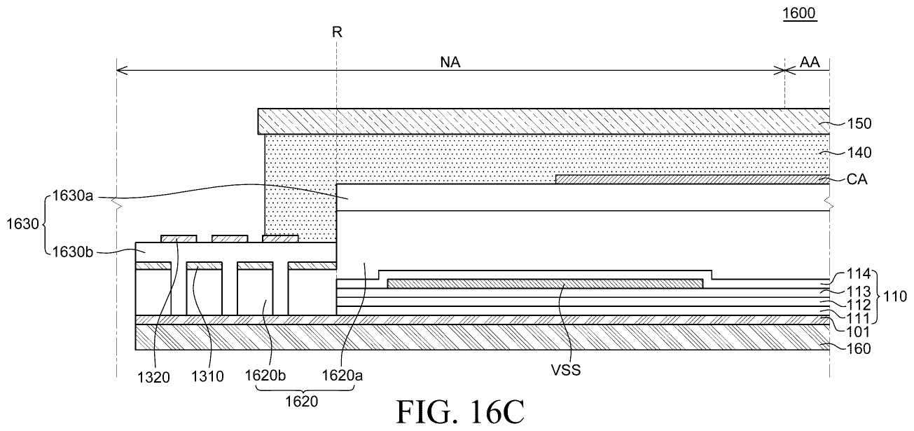

FIG. 16A is a cross-sectional view of a seventh exemplary embodiment taken along the line VIa-VIa′ of FIG. 1. FIG. 16B is a cross-sectional view of a seventh exemplary embodiment taken along VIb-VIb′ of FIG. 1. FIG. 16C is a cross-sectional view of a seventh exemplary embodiment taken along VIc-VIc′ of FIG. 1. The only difference between a display device 1600 of FIGS. 16A to 16C and the display device 1300 of FIGS. 13A to 14C is shapes of the planarization layer 1620 and the bank 1630, but other configurations are substantially the same, so that a redundant description will be omitted.

Referring to FIGS. 16A to 16C, an inorganic layer 110 which is disposed on the entire active area AA and to the reference line R of the non-active area NA is disposed on the first substrate 110 and a planarization layer 1620 and a bank 1630 are sequentially disposed on the inorganic layer 110.

The planarization layer 1620 may include a first planarization layer 1620a and a second planarization layer 1620b. The first planarization layer 1620a is disposed in an area which overlaps the inorganic layer 110 and the second planarization layer 1620b is disposed in an area which does not overlap the inorganic layer 110.

An end of the first planarization layer 1620a is disposed at an end of the inorganic layer 110 and an end of the second planarization layer 1620b coincides with the end of the first substrate 101.

The first planarization layer 1620a and the second planarization layer 1620b may be disposed with different thicknesses. To be more specific, a thickness of the first planarization layer 1620a may be larger than a thickness of the second planarization layer 1620b.

The second planarization layer 1620b may be patterned with a plurality of patterns to expose a top surface of the first substrate 101. The plurality of patterns which forms the second planarization layer 1620b may be disposed to be spaced apart from each other. The width of the plurality of patterns which forms the second planarization layer 1620b may correspond to a width of the plurality of first moisture permeation suppression patterns 1310 disposed on the second planarization layer 1620b. An interval between the plurality of patterns which forms the second planarization layer 1620b may be smaller than the width of the plurality of patterns which forms the second planarization layer 1620b.

As described above, the plurality of first moisture permeation suppression patterns 1310 may be disposed on the patterned second planarization layer 1620b. The plurality of first moisture permeation suppression patterns 1310 is formed of an inorganic material and is spaced apart from each other as much as the interval of the plurality of patterns which forms the second planarization layer 1620b.

The bank 1630 is disposed on the first planarization layer 1620a and the plurality of first moisture permeation suppression patterns 1310.

The bank 1630 includes a first bank 1630a and a second bank 1630b. The first bank 1630a is disposed in an area which overlaps the inorganic layer 110, that is, on the first planarization layer 1620a. The second bank 1630b is disposed in an area which does not overlaps the inorganic layer 110, that is, on the second planarization layer 1620b and the plurality of first moisture permeation suppression patterns 1310.

An end of the first bank 1630a may be disposed at an end of the inorganic layer 110. That is, the end of the first bank 1630a coincides with the end of the first planarization layer 1620a. In contrast, an end of the second bank 1630b coincides with an end of the first substrate 101.

The first bank 1630a and the second bank 1630b may be disposed with different thicknesses. To be more specific, a thickness of the first bank layer 1630a may be larger than a thickness of the second bank layer 1630b.

The second bank 1630b may be disposed to planarize a top surface while being filled in a space between the plurality of patterns which forms the second planarization layer 1620b. If the second bank 1630b opens the space between the plurality of patterns which forms the second planarization layer 1620b without being filled in the space, during the LLO process, heat is concentrated in the open area between the plurality of patterns to excessively crystalize the sacrificial layer used during the LLO process. Therefore, the temporary substrate and the sacrificial layer are detached, the crack may be generated in the first substrate 101 and the planarization layer 1620 and a hole is generated in the planarization layer 1620 due to the crack, which may cause bubbles when the polarizer 160 is adhered. Therefore, the second bank 1630b needs to be disposed to be filled in the space between the plurality of patterns which forms the second planarization layer 1620b.

The plurality of second moisture permeation suppression patterns 1320 is disposed on the second bank 1630b. The plurality of second moisture permeation suppression patterns 1320 is disposed to be spaced apart from each other and an area in which the plurality of second moisture permeation suppression patterns 1320 is disposed may correspond to the space between the plurality of patterns which forms the second planarization layer 1620.

As described above, in the display device 1600 according to still another exemplary embodiment of the present disclosure, the plurality of first moisture permeation suppression patterns 1310 and the plurality of second moisture permeation suppression patterns 1320 which overlap each other are disposed on the second planarization layer 1620b and the second bank 1630b, respectively. In this case, the second planarization layer 1620b is patterned. Therefore, the second bank 1630b is disposed to suppress moisture permeation through the second planarization layer 1620b and to be filled in the space between the plurality of patterns which forms the second planarization layer 1620b. By doing this, a length of the interface between the second planarization layer 1620b and the second bank 1630b is increased to reduce the moisture permeation.

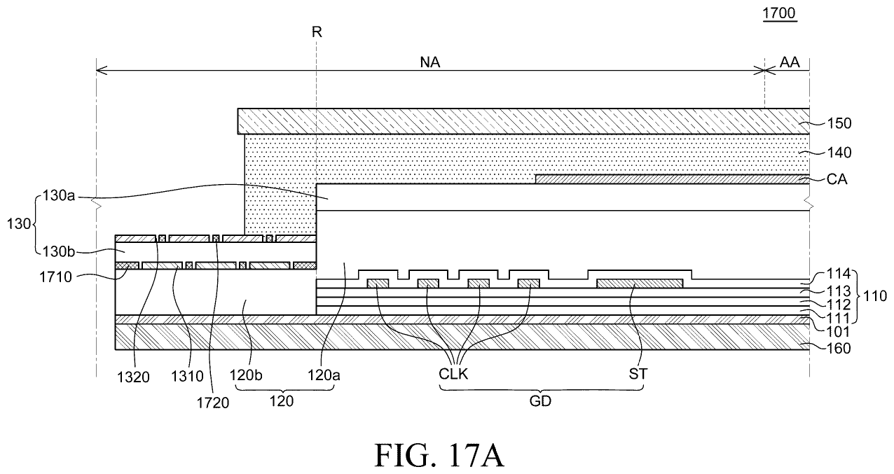

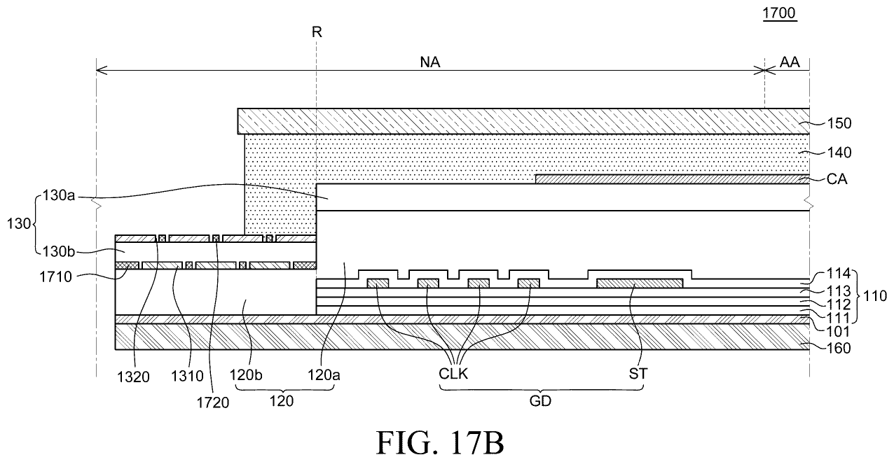

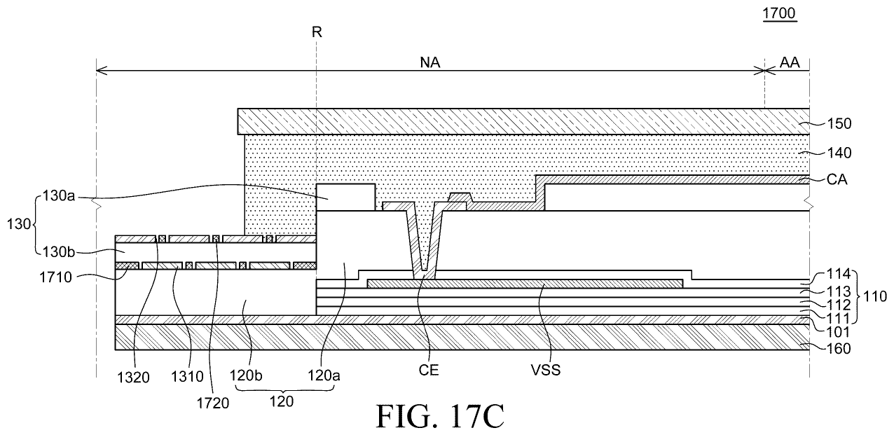

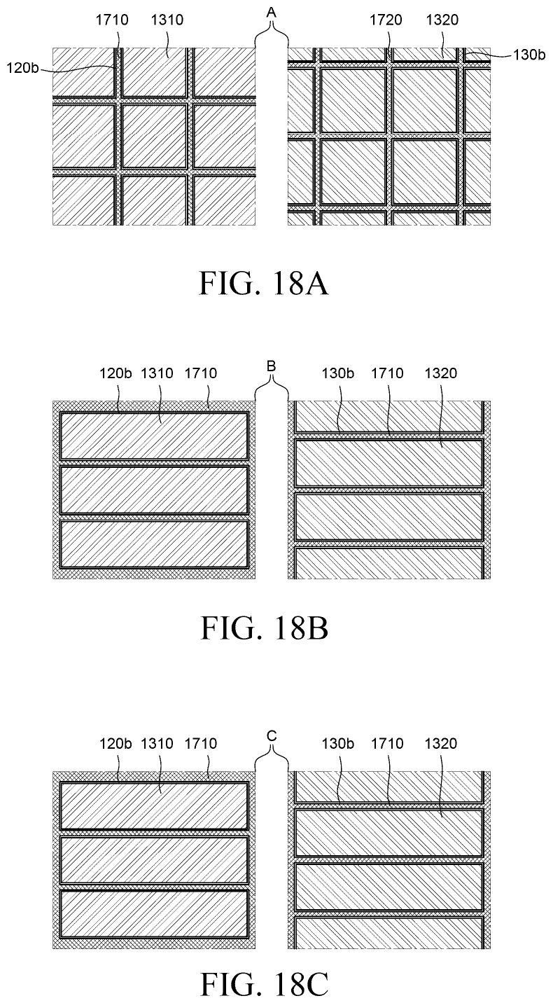

FIG. 17A is a cross-sectional view of an eighth exemplary embodiment taken along the line VIa-VIa′ of FIG. 1. FIG. 17B is a cross-sectional view of an eighth exemplary embodiment taken along VIb-VIb′ of FIG. 1. FIG. 17C is a cross-sectional view of an eighth exemplary embodiment taken along VIc-VIc′ of FIG. 1. FIG. 18A is a schematic enlarged plan view of an area A of FIG. 1 according to an eighth exemplary embodiment. FIG. 18B is a schematic enlarged plan view of an area B of FIG. 1 according to an eighth exemplary embodiment. FIG. 18C is a schematic enlarged plan view of an area C of FIG. 1 according to an eighth exemplary embodiment. The only difference between a display device 1700 of FIGS. 17A to 18C and the display device 1300 of FIGS. 13A to 14C is a plurality of first metal patterns 1710 and a plurality of second metal patterns 1720, but other configurations are substantially the same, so that a redundant description will be omitted.

Referring to FIGS. 17A to 18C, a second planarization layer 120b is disposed on the first substrate 101 on the non-active area NA which does not overlaps the inorganic layer 110.

A plurality of first moisture permeation suppression patterns 1310 which is formed of an inorganic material is disposed on the second planarization layer 120b to be spaced apart from each other and the first metal pattern 1710 is disposed in the space. As described above, the plurality of first moisture permeation suppression patterns 1310 for suppressing moisture permeation is disposed on the second planarization layer 120b and the plurality of first metal patterns 1710 is further disposed in every space between the plurality of first moisture permeation suppression patterns 1310. By doing this, the moisture permeation through the second planarization layer 120b may be more effectively blocked. Further, even though crack is generated by the moisture permeation or impact, the crack propagation to the other layer may be suppressed by the plurality of first metal patterns 1710.

Referring to FIGS. 17A to 18C, the plurality of first metal patterns 1710 is disposed in the space between the plurality of first moisture permeation suppression patterns 1310 and is spaced apart from the adjacent first moisture permeation suppression patterns 1310 with a determined distance. As described above, the first metal pattern 1710 is disposed to be spaced apart from the adjacent first moisture permeation suppression pattern 1310 with a determined distance. This is because when the first moisture permeation suppression pattern 1310 and the first metal pattern 1710 are disposed without a space therebetween by matching the boundaries, if a crack is generated, the crack may more easily propagate.

The second bank 130b is disposed on the second planarization layer 120b in which the first moisture permeation suppression pattern 1310 and the first metal pattern 1710 are disposed.

The plurality of second moisture permeation suppression patterns 1320 which is formed of an inorganic material is disposed on the second bank 130b to be spaced apart from each other and a plurality of second metal patterns 1720 is disposed in every space. At this time, the plurality of second moisture permeation suppression patterns 1320 is disposed so as to overlap an area in which the plurality of first metal patterns 1710 is disposed, that is, a space between the plurality of first moisture permeation suppression patterns 1310. However, the space is a narrow space smaller than a width of each of the plurality of first moisture permeation suppression patterns 1310 and the plurality of second moisture permeation suppression patterns 1320. Therefore, the plurality of first moisture permeation suppression patterns 1310 and some patterns may overlap. Due to this placement, the plurality of second metal patterns 1720 may not overlap the plurality of first metal patterns 1710. As described above, the plurality of second moisture permeation suppression patterns 1320 for suppressing moisture permeation is disposed on the second bank 130b and the plurality of second metal patterns 1720 is further disposed in every space between the plurality of second moisture permeation suppression patterns 1320. By doing this, the moisture permeation through the second bank 130b may be more effectively blocked. Further, even though crack is generated by the moisture permeation or impact, the crack propagation to the other layer may be suppressed by the plurality of second metal patterns 1720.

Referring to FIGS. 17A to 18C, the plurality of second metal patterns 1720 is disposed in the space between the plurality of second moisture permeation suppression patterns 1320 and is spaced apart from the adjacent second moisture permeation suppression patterns 1320 with a determined distance. As described above, the second metal pattern 1720 is disposed to be spaced apart from the adjacent second moisture permeation suppression pattern 1320 with a determined distance. This is because when the second moisture permeation suppression pattern 1320 and the second metal pattern 1710 are disposed without a space therebetween by matching the boundaries, if a crack is generated, the crack may more easily propagate.

As described above, the plurality of first moisture permeation suppression patterns 1310 and the plurality of second moisture permeation suppression patterns 1320 for suppressing the moisture permeation are disposed on the second planarization layer 120b and the second bank 130b, respectively. Further, the plurality of first metal patterns 1710 is disposed in a space between the plurality of first moisture permeation suppression patterns 1310 and the plurality of second metal patterns 1720 is disposed in a space between the plurality of second moisture permeation suppression patterns 1320. By doing this, the moisture permeation through the organic layers (that is, the second planarization layer 120b and the second bank 130b) in the outer peripheral portion may be more effectively blocked. Further, even though the crack is generated, the crack propagation may be effectively blocked.

The exemplary embodiments of the present disclosure can also be described as follows:

According to an aspect of the present disclosure, a display device, comprise a first substrate which includes an active area including a plurality of sub pixels and a non-active area enclosing the active area and is formed of one of transparent conducting oxide and an oxide semiconductor, an inorganic layer which is disposed on the first substrate and has an end located at the inside of the first substrate, a planarization layer disposed on the inorganic layer and the first substrate, and a bank disposed on the planarization layer, the planarization layer includes a first planarization layer disposed in an area which overlaps the inorganic layer and a second planarization layer disposed to cover a top surface of the first substrate exposed by the inorganic layer, the bank includes a first bank disposed on the first planarization layer and a second bank disposed on the second planarization layer, and thicknesses of the second planarization layer and the second bank are smaller than thicknesses of the first planarization layer and the first bank.

The first bank and the second bank may be connected.

The first bank and the second bank may be spaced apart from each other.

The display device may further comprise a first moisture permeation suppression layer which is disposed on the second planarization layer and is formed of an inorganic material, and a second moisture permeation suppression layer which is disposed on the second bank and is formed of an inorganic material.

The display device may further comprise a plurality of first moisture permeation suppression patterns which is disposed on the second planarization layer and is formed of an inorganic material, and a plurality of second moisture permeation suppression patterns which is disposed on the second bank and is formed of an inorganic material.

The plurality of first moisture permeation suppression patterns and the plurality of second moisture permeation suppression patterns are spaced apart from each other and the plurality of second moisture permeation suppression patterns may be disposed to overlap a space between the plurality of first moisture permeation suppression patterns.

The space may be equal to or larger than a width of the plurality of second moisture permeation suppression patterns.

The plurality of first moisture permeation suppression patterns and the plurality of second moisture permeation suppression patterns are spaced apart from each other and the plurality of second moisture permeation suppression patterns may be disposed to partially overlap the plurality of first moisture permeation suppression patterns.

The second planarization layer includes a plurality of patterns which is spaced apart from each other, the plurality of first moisture permeation suppression patterns is disposed on the plurality of patterns and the plurality of second moisture permeation suppression patterns may be disposed to overlap a space between the plurality of patterns.

The second bank may be disposed to be filled in the space between the plurality of patterns.

The display device may further comprise a plurality of first metal patterns disposed in a space between the plurality of first moisture permeation suppression patterns, and a plurality of second metal patterns disposed in a space between the plurality of second moisture permeation suppression patterns.

Each of the plurality of first metal patterns is disposed to be spaced apart from the plurality of first moisture permeation suppression patterns and each of the plurality of second metal patterns may be disposed to be spaced apart from the plurality of second moisture permeation suppression patterns.

According to another aspect of the present disclosure, a display device, comprise a first substrate which includes an active area and a non-active area enclosing the active area and is formed of one of transparent conducting oxide and an oxide semiconductor, an inorganic layer which is disposed on the first substrate and has an end located at the inside of the first substrate in the non-active area, a first planarization layer disposed on the inorganic layer, a second planarization layer which is disposed in the non-active area of the first substrate whose top surface is exposed by the inorganic layer, a first bank disposed on the first planarization layer, a plurality of first moisture permeation suppression patterns disposed on the second planarization layer, a second bank disposed on the plurality of first moisture permeation suppression pattern, and a plurality of second moisture permeation suppression patterns disposed on the second bank, the non-active area includes a first non-active area in which a gate driver is disposed, a second non-active area between the plurality of flexible films in an area connected to a plurality of flexible films, and a third non-active area which is an opposite area to the area connected to the plurality of flexible films, the plurality of first moisture permeation suppression patterns and the plurality of second moisture permeation suppression patterns disposed in the first non-active area are different from the plurality of first moisture permeation suppression patterns and the plurality of second moisture permeation suppression patterns disposed in the second non-active area and the third non-active area.

Thicknesses of the first planarization layer and the first bank may be larger than thicknesses of the second planarization layer and the second bank.

The plurality of first moisture permeation suppression patterns and the plurality of second moisture permeation suppression patterns disposed in the second non-active area and the third non-active area are disposed in a first direction and the plurality of first moisture permeation suppression patterns and the plurality of second moisture permeation suppression patterns disposed in the first non-active area may be disposed in a second direction intersecting the first direction.

The plurality of first moisture permeation suppression patterns and the plurality of second moisture permeation suppression patterns disposed in the first non-active area, the second non-active area and the third non-active area may be alternately disposed in plan view.

The plurality of first moisture permeation suppression patterns and the plurality of second moisture permeation suppression patterns may be spaced apart from each other in plan view.

Boundaries of the plurality of first moisture permeation suppression patterns and the plurality of second moisture permeation suppression patterns may coincide with each other.

The plurality of first moisture permeation suppression patterns and the plurality of second moisture permeation suppression patterns disposed in the first non-active area are alternately disposed in the first direction and the second direction, the plurality of first moisture permeation suppression patterns and the plurality of second moisture permeation suppression patterns disposed in the second non-active area and the third non-active area are disposed in the first direction, and the plurality of first moisture permeation suppression patterns and the plurality of second moisture permeation suppression patterns disposed in the first non-active area may have an island shape.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present application should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first substrate which includes an active area including a plurality of sub pixels and a
non-active area enclosing the active area and is formed of one of a transparent conducting oxide or an oxide semiconductor, the first substrate includes an inside portion and an edge portion that is outside of the inside portion;
an inorganic layer which is disposed on the first substrate and has an end located at the inside portion of the first substrate, and the edge portion of the first substrate being offset from the inorganic layer;
a planarization layer disposed on the inorganic layer and the first substrate; and
a bank disposed on the planarization layer,
wherein the planarization layer includes a first planarization layer disposed in an area which overlaps the inorganic layer and a second planarization layer that covers a top surface of the edge portion of the first substrate, the bank includes a first bank disposed on the first planarization layer and a second bank disposed on the second planarization layer, and a combined thickness of the second planarization layer and the second bank is smaller than a combined thicknesses of the first planarization layer and the first bank.

2. The display device according to claim 1, wherein the first bank and the second bank are connected.

3. The display device according to claim 1, wherein the first bank and the second bank are spaced apart from each other.

4. The display device according to claim 3, further comprising:
a first moisture permeation suppression layer which is disposed on the second planarization layer and includes an inorganic material; and
a second moisture permeation suppression layer which is disposed on the second bank and includes an inorganic material.

5. The display device according to claim 3, further comprising:
a plurality of first moisture permeation suppression patterns which are disposed on the second planarization layer and include an inorganic material; and
a plurality of second moisture permeation suppression patterns which are disposed on the second bank and include an inorganic material.

6. The display device according to claim 5, wherein the plurality of first moisture permeation suppression patterns and the plurality of second moisture permeation suppression patterns are spaced apart from each other and the plurality of second moisture permeation suppression patterns each overlap a space among the first moisture permeation suppression patterns of the plurality of first moisture permeation suppression patterns.

7. The display device according to claim 6, wherein the space includes a dimension that is equal to or larger than a width of a second moisture permeation suppression pattern of the plurality of second moisture permeation suppression patterns.

8. The display device according to claim 5, wherein the plurality of first moisture permeation suppression patterns and the plurality of second moisture permeation suppression patterns are spaced apart from each other and the plurality of second moisture permeation suppression patterns each partially overlaps a first moisture permeation suppression pattern of the plurality of first moisture permeation suppression patterns.

9. The display device according to claim 5, wherein the second planarization layer includes a plurality of patterns which are spaced apart from each other, the plurality of first moisture permeation suppression patterns are disposed on the plurality of patterns and the plurality of second moisture permeation suppression patterns each overlaps a space among patterns of the plurality of patterns.

10. The display device according to claim 9, wherein the second bank is filled in the space among patterns of the plurality of patterns.

11. The display device according to claim 5, further comprising:
a plurality of first metal patterns each disposed in a space among first moisture permeation suppression patterns of the plurality of first moisture permeation suppression patterns; and
a plurality of second metal patterns each disposed in a space among second moisture permeation suppression patterns of the plurality of second moisture permeation suppression patterns.

12. The display device according to claim 11, wherein each of the plurality of first metal patterns is spaced apart from the plurality of first moisture permeation suppression patterns and each of the plurality of second metal patterns is spaced apart from the plurality of second moisture permeation suppression patterns.

13. A display device, comprising:
a plurality of flexible films;
a first substrate which includes an active area and a non-active area adjacent to the active area and is formed of one of transparent conducting oxide or an oxide semiconductor, the first substrate includes an inside portion and an edge portion that is outside of the inside portion;
an inorganic layer which is disposed on the first substrate and has an end located at the inside portion of the first substrate in the non-active area, and the edge portion of the first substrate being offset from the inorganic layer;
a first planarization layer disposed on the inorganic layer;
a second planarization layer disposed in the edge portion of the first substrate;
a first bank disposed on the first planarization layer;
a plurality of first moisture permeation suppression patterns disposed on the second planarization layer;
a second bank disposed on the plurality of first moisture permeation suppression pattern; and
a plurality of second moisture permeation suppression patterns disposed on the second bank,
wherein the non-active area includes a first non-active area in which a gate driver is disposed, a second non-active area in an area connected to the plurality of flexible films, and a third non-active area which is in an area opposite to the area connected to the plurality of flexible films, first moisture permeation suppression patterns and second moisture permeation suppression patterns disposed in the first non-active area are different from first moisture permeation suppression patterns and second moisture permeation suppression patterns disposed in the second non-active area and the third non-active area.

14. The display device according to claim 13, wherein a combined thickness of the first planarization layer and the first bank is larger than a combined thickness of the second planarization layer and the second bank.

15. The display device according to claim 14, wherein the first moisture permeation suppression patterns and the second moisture permeation suppression patterns disposed in the second non-active area and the third non-active area are disposed in a first direction and the first moisture permeation suppression patterns and the second moisture permeation suppression patterns disposed in the first non-active area are disposed in a second direction traversing the first direction.

16. The display device according to claim 15, wherein the first moisture permeation suppression patterns and the second moisture permeation suppression patterns disposed in the first non-active area, the second non-active area and the third non-active area are alternately disposed in plan view.

17. The display device according to claim 16, wherein the plurality of first moisture permeation suppression patterns and the plurality of second moisture permeation suppression patterns are spaced apart from each other in a plan view.

18. The display device according to claim 16, wherein boundaries of the plurality of first moisture permeation suppression patterns and the plurality of second moisture permeation suppression patterns coincide with each other.

19. The display device according to claim 14, wherein the plurality of first moisture permeation suppression patterns and the plurality of second moisture permeation suppression patterns disposed in the first non-active area are alternately disposed in a first direction and a second direction that traverses the first direction, the plurality of first moisture permeation suppression patterns and the plurality of second moisture permeation suppression patterns disposed in the second non-active area and the third non-active area are disposed in the first direction, and the plurality of first moisture permeation suppression patterns and the plurality of second moisture permeation suppression patterns disposed in the first non-active area each has an island shape.

20. A display device, comprising:
a first substrate having a first area and a second area laterally adjacent to the first area;
an inorganic layer on the first area of the first substrate and offsetting from the second area of the first substrate;
a first planarization layer on the inorganic layer;
a second planarization layer on the second area of the first substrate;
a first bank on the first planarization layer;
a second bank on the second planarization layer; and
a plurality of moisture permeation suppression patterns on the second planarization layer, the plurality of moisture permeation suppression patterns spaced apart from one another.

21. The display device of claim 20, wherein the plurality of moisture permeation suppression patterns are spaced apart from one another in one or more of a vertical direction or a lateral direction.

22. The display device of claim 20, wherein the plurality of moisture permeation suppression patterns at least partially offset from one another in a vertical direction.
